(19) United States
(12) Patent Application Publication
(10) Pub. No.: US 2016/0155974 A1
(43) Pub. Date: Jun. 2, 2016

(54) COMPLEX PNICTIDE METAL HALIDES FOR OPTOELECTRONIC APPLICATIONS

(71) Applicants: Mitsubishi Chemical Corporation, Tokyo (JP); The Regents of the University of California, Oakland, CA (US)

(72) Inventors: Hengbin Wang, Santa Barbara, CA (US); Ram Seshadri, Goleta, CA (US); Michael Chabinyc, Santa Barbara, CA (US); Anna Lehner, Freiburg (DE); Christopher Liman, Santa Barbara, CA (US)

(73) Assignees: The Regents of the University of California, Oakland, CA (US); Mitsubishi Chemical Corporation, Tokyo (JP)

(21) Appl. No.: 14/954,131

(22) Filed: Nov. 30, 2015

Related U.S. Application Data
(60) Provisional application No. 62/085,885, filed on Dec. 1, 2014.

(51) Int. Cl. H01L 51/42; H01L 31/18

(52) U.S. Cl. CPC H01L 51/4226; H01L 31/18

(57) ABSTRACT

An optoelectronic device comprising an active layer sandwiched between a first electrode and a second electrode. The active layer comprises a material of the formula AₐB_{b}MₘXₓ, wherein A represents a monovalent inorganic cation, a monovalent organic cation, or mixture of different monovalent organic or inorganic cations; B represents a divalent inorganic cation, a divalent organic cation, or mixture of different divalent organic or inorganic cations; M represents Bi³⁺ or Sb³⁺; X represents a monovalent halide anion, or mixture of different monovalent halide anions; and a, b represent 0 or any positive numbers, m, x represent any positive numbers, and a+2b+3m=x.

### REFERENCE TO RELATED APPLICATIONS

This application claims priority under Section 119(e) from U.S. Provisional Application Ser. No. 62/085,885, filed Dec. 1, 2014, entitled “COMPLEX PNICTIDE METAL HALIDES FOR OPTOELECTRONIC APPLICATIONS” by Hengbin Wang et al., the contents of which are incorporated herein by reference.

### TECHNICAL FIELD

The invention relates to optoelectronic devices and in particular active layers for solar cell devices.

### BACKGROUND OF THE INVENTION

In recent years, tremendous effort has been dedicated to the search of new photovoltaic (PV) materials, which offer advantages over established technologies and meet the requirements for a wide range of applications. As an alternative to Si and GaAs based technologies, thin-film devices using chalcogenides such as CuInₓGa(₁₋ₓ)Se₂ (CIGS) [1] or CdTe [2] have currently reached more than 20% photoconversion efficiency (PCE), which approaches the PCE of the best Si-based devices (27.6% Amonix). Other emerging photovoltaics are organic or dye-sensitized solar cells, as well as quantum dot devices [3, 4]. As most of these technologies rely on one or more elements which are of limited availability (such as In, Ga for CIGS, Te for CdTe, Ru for dye-sensitized solar cells, or Ag for the production of crystalline Si), there is a need for the development of new PV technology based on abundant and low-cost elements.

The application of inorganic kesterite type materials such as Cu₂ZnSn(S,Se)₄, which are based on more earth-abundant elements in solar cells, has kindled research efforts and brought forth devices with PCEs of over 10% [5]. Most recently, solar cells based on hybrid organic-inorganic halide lead perovskites A[PbX₃] (where A=CH₃NH₃⁺ (MA) or NH₂(CH)NH₂⁺ (FA); X=Cl, Br, or I) which could potentially offer high PCEs and low processing costs have been attracting immense interest [6]. Since the first report in 2009 [7] the best halide lead perovskite solar cell have reached 19.3% PCE in 2014 [8] and 20.1% PCE was announced in 2015. Although progress in material and device optimization has been remarkable over the last years, there are still several technical challenges. These include the instability of those materials to atmospheric moisture and the toxicity of soluble lead materials. Solar cells with a tin analogue of the lead perovskites have been described, but their PCEs are considerably lower than the best lead-based devices and the materials are very air and moisture sensitive [9].

### SUMMARY OF THE INVENTION

This invention describes optoelectronic devices having a solid state thin film active layer comprising solution-processable, non-toxic semiconducting bismuth halide complex materials. In particular, this invention describes solar cell devices comprising a solution-processable, non-toxic bismuth halide complex active layer.

In one aspect of the present invention, a solid state thin film optoelectronic device is provided. The optoelectronic device comprises a semiconducting active layer sandwiched between a first electrode and a second electrode. The active layer comprises a material of the formula AₐB_{b}MₘXₓ, wherein A represents a monovalent inorganic cation, a monovalent organic cation or mixture of different monovalent organic or inorganic cations; B represents a divalent inorganic cation, a divalent organic cation or mixture of different divalent organic or inorganic cations; M is Bi³⁺ or Sb³⁺; X represents a monovalent halide anion, or mixture of different monovalent halide anions; a, b represent 0 or any positive numbers, m, x represent any positive numbers, and a+2b+3m=x.

Embodiments of the optoelectronic device may have a standard or inverted structure. The optoelectronic device may further comprise a substrate, an first electrode deposited on the substrate, a second electrode, an optional electron conducting/hole blocking layer deposited either between the first electrode and the active layer, or between the active layer and the second electrode, and an optional hole conducting/electron blocking layer deposited either in between the first electrode and the active layer, or between the active layer and the second electrode. In one or more embodiments, the optoelectronic device may further comprise a mesoporous electron conducting layer between the electron conducting/hole blocking layer and the active layer.

In one or more embodiments, A is selected from the group consisting of H⁺, H₃O⁺, NH₄⁺, H₃NOH⁺, Li⁺, Na⁺, K⁺, Rb⁺, Cs⁺, Cu⁺, Ag⁺, BiO⁺, methylammonium CH₃NH₃⁺, ethylammonium (C₂H₅)NH₃⁺, alkylammonium, formamidinium NH₂(CH)NH₂⁺, guanidinium C(NH₂)₃⁺, imidazolium C₃N₂H₅⁺, hydrazinium H₂N—NH₃⁺ azetidinium (CH₂)₃NH₂⁺, dimethylammonium (CH₃)₂NH₂⁺, tetramethylammonium (CH₃)₄N⁺, phenylammonium C₆H₅NH₃⁺, arylammonium, and heteroarylammonium. In one or more embodiments, B is a divalent primary, secondary, tertiary, or quaternary organic ammonium cation with 1 to 100 carbons and 2 to 30 heteroatoms, wherein two of the heteroatoms are positively charged nitrogen atoms. In certain instances, B is selected from the group consisting of Mg²⁺, Ca²⁺, Sr²⁺, Ba²⁺, Sn²⁺, Ti²⁺, V²⁺, Ni²⁺, Cr²⁺, Co²⁺, Fe²⁺, Cu²⁺, Zn²⁺, Mn²⁺, Ag²⁺, NH₃CH₂CH₂NH₃²⁺, NH₃(CH₂)₆NH₃²⁺, NH₃(CH₂)₈NH₃²⁺, and NH₃C₆H₄NH₃²⁺

In one or more embodiments, the active layer comprises a material selected from the group consisting of MX₃, AMX₄, A₃MX₆, A₃M₂X₉, perovskites, A₂A′MX₆ double perovskites, and Aₙ₊₁A′_{n/2}M_{n/2}X₃ₙ₊₁ Ruddlesden-Popper phases. wherein A represents a monovalent inorganic cation, a monovalent organic cation; A′ represents a second monovalent organic or inorganic cation; M is Bi³⁺ or Sb³⁺; X represents a monovalent halide anion, or mixture of different monovalent halide anions. As used herein, the term “double perovskite” refers to a compound which is closely related to the perovskite AMX₃ compound but has a unit cell twice that of perovskite and two different metals on the M sites, so the formula can be written as A₂A′MX₆. The term “Ruddlesden-Popper phase” as used herein refers to a form of layered perovskite structures which consist of two-dimensional perovskite slabs and additional cation interlayers. The general formula of those phases can be written as Aₙ₊₁A′_{n/2}M_{n/2}X₃ₙ₊₁. In certain instances, the active layer is a bismuth halide selected from the group consisting of BiI₃, K₃Bi₂I₉, Rb₃Bi₂I₉, Cs₃Bi₂I₉, (CH₃NH₃)₃Bi₂I₉, (NH₂(CH)NH₂)₃Bi₂I₉, and (NH₃(CH₂)₂NH₃)₂Bi₂I₁₀.

As described in further detail in the Example section below, a variety of bismuth based perovskite-related materials AₐB_{b}MₘXₓ, containing [MX₆] octahedra connected via shared apexes, edges or faces were synthesized. Their crystal structures, optical property, energy levels and film morphology were characterized. Solar cell devices based on these bismuth halide complexes were successfully fabricated by a solution process and evaluated. Promising photovoltaic property was demonstrated.

Other objects, features and advantages of the present invention will become apparent to those skilled in the art from the following detailed description. It is to be understood, however, that the detailed description and specific examples, while indicating some embodiments of the present invention, are given by way of illustration and not limitation. Many changes and modifications within the scope of the present invention may be made without departing from the spirit thereof, and the invention includes all such modifications.

### BRIEF DESCRIPTION OF THE DRAWINGS

Referring now to the drawings in which like reference numbers represent corresponding parts throughout:

FIG. 1 shows various potential hole transport materials with low HOMO energies, in accordance with one or more embodiments of the present invention. (FIG. 1A) 1,3-Bis(N-carbazolyl)benzene, (FIG. 1B) 4,4′-Bis(N-carbazolyl)-1,1′-biphenyl, (FIG. 1C) N,N′-Bis(3-methylphenyl)-N,N′-diphenylbenzidine, (FIG. 1D) Copper(II) phthalocyanine, (FIG. 1E) 4,4′-Cyclohexylidenebis[N,N-bis(4-methylphenyl)benzenamine], (FIG. 1F) 9,9-Dimethyl-N,N′-di(1-naphthyl)-N,N′-diphenyl-9H-fluorene-2,7-diamine, (FIG. 1G) N,N′-Di(1-naphthyl)-N,N′-diphenyl-(1,1′-biphenyl)-4,4′-diamine, (FIG. 1H) Poly(9-vinylcarbazole), (FIG. 1I) Tris(4-carbazoyl-9-ylphenyl)amine, (FIG. 1J) 1,3,5-Tris(2-(9-ethylcabazyl-3)ethylene)benzene, (FIG. 1K) Poly(9,9-di-n-dodecylfluorenyl-2,7-diyl), (FIG. 1L) 1,3,5-Tris(N-carbazolyl)benzene, (FIG. 1M) 3,6-Bis(N-carbazolyl)-N-phenylcarbazole.

FIG. 2 shows optical microscopy photographs of A₃Bi₂I₉ and (NH₂(CH)NH₂)₃Bi₂I₉ salts: (FIG. 2A) A=K (1), (FIG. 2B) A=Rb (2), (FIG. 2C) A=Cs (3), (FIG. 2D) A=CH₃NH₃ (4), (FIG. 2E) A=NH₂(CH)NH₂ (5), (FIG. 2F) (NH₃(CH₂)₂NH₃)₂Bi₂I₁₀ (6).

FIG. 3 shows experimental and simulated (a: from ref. [16a], b: from ref. [16b]) X-ray powder diffraction patterns of A₃Bi₂I₉, A=K (1, FIG. 3A), A=Rb (2, FIG. 3B).

FIG. 4 shows experimental and simulated (a: from ref. [15a], b: from own single crystal data) X-ray powder diffraction patterns of A₃Bi₂I₉, A=Cs (3, FIG. 4A), A=CH₃NH₃ (4, FIG. 4B).

FIG. 5 shows experimental and simulated (a: from own single crystal data, b: from ref [28], b:) X-ray powder diffraction patterns of (NH₂(CH)NH₂)₃Bi₂I₉ (5, FIG. 5A), (NH₃(CH₂)₂NH₃)₂Bi₂I₁₀ (6, FIG. 5B).

FIG. 6 shows various crystal structure types of A₃Bi₂I₉ salts: A=K, Rb (1, 2, monoclinic, P2₁/c, FIG. 6A), A=Cs (3, P6₃/mmc, FIG. 6B). The room temperature structures of (CH₃NH₃)₃Bi₂I₉ (4) and (NH₂(CH)NH₂)₃Bi₂I₉ (5) are very similar to the Cs₃Bi₂I₉ structure but the organic cations are heavily disordered.

FIG. 7 shows the chemical structure of 1-pyrenemethylammonium iodide and crystal structure of Py₃Bi₂I₉. The 1-pyrenemethylammonium bismuth iodide obtained possesses 0D face sharing Bi₂I₉³⁻ octahedra creating pseudo layers, with disordered yet partially pi-pi stacked pyrene molecules lying in the interlayer voids.

FIG. 8 shows the crystal structures of Ag_{0.828}BiI₄ (FIG. 8A, from ref [41]), Ag_{1.87}Bi_{1.38}I₆ (FIG. 8B, from own single crystal data) and Cu_{0.99}BiI₄ (FIG. 8C, from ref [42]). The related crystal structures of black Ag_{1-δ}Bi_{1+δ/3}I₄ and Cu_{1-δ}Bi_{1+δ/3}I₄ are based on a fcc packing of iodine, and δ represent a positive number between 0 to 1. In Ag_{0.828}BiI₄ both cations are disordered on the same octahedral site. Site occupancies is Bi (0.5), Ag (0.414) in Ag_{0.828}BiI₄, and crystal parameters are Fd3m, a=12.22 Å, V=1826.00 Å³. A dark red crystal of the Ag_{3-3δ}Bi_{1+δ}I₆ phase was achieved and measured, crystal parameters are R3m, a=4.34 Å, c=20.75 Å, V=337.70 Å³.

FIG. 9 shows PXRD pattern for a sample of the target composition Ag_{0.8}Bi₂I_{6.8} made by ball-milling for 10 min at RT (FIG. 9A), and PXRD pattern for a sample of the target composition AgBiI₄ made by ball-milling for 10 min at RT (FIG. 9B).

FIG. 10 shows UV-Vis spectra recorded in diffuse reflection mode on powder samples of 1-6 mixed with BaSO₄, converted into absorbance by a Kubelka-Munch transformation. Band gap energies E_{g} (in eV) determined by Tauc plots assuming direct band gaps.

FIG. 11 shows UV-Vis spectra of BiI₃ recorded in diffuse reflection mode on a powder sample mixed with BaSO₄ (converted into absorbance by a Kubelka-Munch transformation) and in transmission mode on thin film drop-cast from DMF solution on a quartz slide. In both cases, the band gap was determined to be 1.7 eV.

FIG. 12 shows scanning electron microscope images of Rb₃Bi₂I₉ (2) films drop-cast from DMF on quartz slides.

FIG. 13 shows scanning electron microscope images of (CH₃NH₃)₃Bi₂I₉ (3) films drop-cast from DMF on quartz slides.

FIG. 14 shows a XPS spectrum recorded on a film of BiI₃ drop-cast from DMF in air.

FIG. 15 shows a XPS spectrum recorded on a film of Rb₃Bi₂I₉ (2) drop-cast from DMF in air.

FIG. 16 shows a XPS spectrum recorded on a film of (CH₃NH₃)₃Bi₂I₉ (3) drop-cast from DMF in air.

FIG. 17 shows XPS and UPS spectra recorded a thin film of K₃Bi₂I₉ (1). Low oxygen and carbon impurities are typically observed as consequence of sample preparation, the composition derived from the XPS data is K_{3.2}Bi_{2.0}I_{9.8} which is in good agreement with the nominal composition.

FIG. 18 shows UPS spectra of three example compounds; samples prepared by drop-casting in air.

FIG. 19 shows an energy band diagram including the measured optical band gap, valence band edge, and conduction band edge for three example bismuth compounds together with the conduction band minima/valence band maxima of (CH₃NH₃)PbI₃ (data from reference [30]) and common electron/hole transport materials and the relevant band energies of the electrodes FTO and gold.

FIG. 20 shows J-V (FIG. 20A) and EQE (FIG. 20B) plots of BiI₃ solar cells with a dense TiO₂ hole blocking layer, a mesoporous TiO₂ layer on some samples, and PTAA electron blocking layer.

FIG. 21 shows BiI₃ solar cell devices using PTAA or PIDT-DFBT as the HTL. (FIG. 21A) SEM cross section and schematic device architecture, (FIG. 21B) external quantum efficiency, and (FIG. 21C) JV traces of the assembled devices.

### DETAILED DESCRIPTION OF THE INVENTION

Many of the techniques and procedures described or referenced herein are well understood and commonly employed using conventional methodology by those skilled in the art. In the description of the preferred embodiment, reference may be made to the accompanying drawings which form a part hereof, and in which is shown by way of illustration a specific embodiment in which the invention may be practiced. It is to be understood that other embodiments may be utilized and structural changes may be made without departing from the scope of the present invention.

Unless otherwise defined, all terms of art, notations and other scientific terms or terminology used herein are intended to have the meanings commonly understood by those of skill in the art to which this invention pertains. In some cases, terms with commonly understood meanings are defined herein for clarity and/or for ready reference, and the inclusion of such definitions herein should not necessarily be construed to represent a substantial difference over what is generally understood in the art.

Note: This application references a number of different publications as indicated throughout the specification by one or more reference numbers within brackets, e.g., [x]. A list of these different publications ordered according to these reference numbers can be found below in the section entitled “REFERENCES”. Each of these publications is incorporated by reference herein. All publications, patents, and patent applications cited herein are hereby incorporated by reference in their entirety for all purposes. Publications cited herein are cited for their disclosure prior to the filing date of the present application. Nothing here is to be construed as an admission that the inventors are not entitled to antedate the publications by virtue of an earlier priority date or prior date of invention. Further the actual publication dates may be different from those shown and require independent verification.

### ABBREVIATIONS

1=K₃Bi₂I₉
2=Rb₃Bi₂I₉
3=Cs₃Bi₂I₉
4=(MA)₃Bi₂I₉
5=(FA)₃Bi₂I₉
6=(EDA)₂Bi₂I₁₀
MA=Methylammonium, (CH₃NH₃)⁺
FA=Formamidinium, (NH₂(CH)NH₂)⁺
EDA=Ethylenediammonium, (NH₃(CH₂)₂NH₃)²⁺
HDA=1,6-Hexanediammonium, (NH₃(CH₂)₆NH₃)²⁺
DMF=N,N-Dimethylformamide
DMAc=Dimethylacetamide
Spiro-MeOTAD=N²,N²,N²′,N²′,N⁷,N⁷,N⁷′,N⁷′-octakis(4-methoxyphenyl)-9,9′-spirobi[9H-fluorene]-2,2′,7,7′-tetramine
PTAA=Poly[bis(4-phenyl)(2,4,6-trimethylphenyl)amine]
PEDOT:PSS=Poly(3,4-ethylenedioxythiophene) Polystyrene sulfonate
P3HT=Poly(3-hexylthiophene-2,5-diyl)
Ti(OiPr)₄=Titanium tetraisopropoxide
Li-TFSI=Bis(trifluoromethane)sulfonimide lithium salt
Py=1-Pyrenemethylammonium

The present invention addresses the challenges described above and others by introducing new chemistry. In one or more embodiments, the pnictide element bismuth is used as the central metal in complex, perovskite-related compounds. In other embodiments, the pnictide element antimony is used as the central metal. “Pnictide element” refers to a member of the 15th group in the periodic table. Bismuth is industrially considered as one of the less toxic heavy metals and is, contrary to lead, rated as not being bio-accumulative, carcinogenic, or a cause of birth defects. The family of bismuth halides comprises a great variety of compounds, which have recently been studied for their rich structural chemistry and interesting properties, such as ferroelectricity, nonlinear optical effects, and absorption of hard radiation [10]. While there are extensive studies of devices based on lead and tin halides, the fabrication and testing of the optoelectronic behavior of bismuth halide devices has not been widely explored. To our knowledge, the only report of a bismuth halide material tested in a solar cell device was published on a cell using BiI₃ as a hole-transport material in a poly-3-hexyl thiophene (P3HT), phenyl-C₆₁-butyric acid methyl ester (PCBM) device [11]. There have been proposals to use bismuth halides BiX₃ or BiOX as the light absorbing dye material in a dye sensitized solar cell with a redox electrolyte layer sandwiched there between, but no device data have been demonstrated [37]. For single junction solar cells, the highest efficiencies can be theoretically expected for absorber materials with band gaps close to 1.34 eV, while complex metalates of the main group heavy metals with larger band gaps can be potentially applied in a wide field of other applications.

The term “perovskite”, as used herein refers to a material with a three-dimensional crystal structure related to that of SrTiO₃ or a material comprising a layer of material, wherein the layer has a structure related to that of SrTiO₃. The perovskite structure can be represented by the formula AMX₃, wherein A and M are cations of different sizes, typically A having a charge of +1 and M having a charge of +2 and X is an anion (charge −1). When A, M and X are varied, the different ion sizes may cause the structure of the perovskite material to distort away from the highly symmetric cubic structure adopted by SrTiO₃ to a lower-symmetry distorted structure. The symmetry will also be lower if the material comprises a layer that has a structure related to that of SrTiO₃. A perovskite material can be represented by the formula AMX₃, wherein A is at least one cation, M is at least one cation and X is at least one anion. When the perovskite comprises more than one A cation, the different A cations may be distributed over the A sites in an ordered or disordered way. When the perovskite comprises more than one M cation, the different M cations may be distributed over the M sites in an ordered or disordered way. When the perovskite comprises more than one X anion, the different X anions may be distributed over the X sites in an ordered or disordered way. In the optoelectronic device of the invention, the perovskite may comprises a first cation, a second cation, and at least one anion. As the skilled person will appreciate, the perovskite may comprise further cations or further anions. For instance, the perovskite may comprise two, three or four different first cations; two, three or four different second cations; or two, three of four different anions.

In one or more embodiments, the invention focuses on bismuth iodides, due to the fact that their band gaps are lowest among the bismuth halides. However, as devices made from chloride-containing methylammonium lead iodide have been reported to offer solar performances superior to cells of pristine (CH₃NH₃)PbI₃ [12] and because the dependence of crystal chemistry and optoelectronic properties on the nature of the anions are not yet well understood, the variation of anions is very relevant. Binary BiI₃ and SbI₃ are interesting semiconductors with crystal structures featuring layers of edge-sharing [MI₆]³⁻ octahedra.

The term “semiconductor” as used herein refers to a material with electrical conductivity intermediate in magnitude between that of a conductor and a dielectric. The semiconductor may be an n-type semiconductor, a p-type semiconductor or an intrinsic semiconductor. As used herein, the term “n-type”, refers to an electron transporting material. The n-type semiconductor used in the present invention may be any suitable semiconductor with the ability to transport electrons either as an intrinsic semiconducting material or electrically doped to transport dominantly electrons. As used herein, the term “p-type”, refers to a hole transporting material. The p-type semiconductor used in the present invention may be any suitable semiconductor with the ability to transport holes either as an intrinsic semiconducting material or electrically doped to transport dominantly holes. The intrinsic semiconductor used in the present invention may be any suitable intrinsic semiconductor.

Extending the composition of binary halides by introducing counter cations or substituting the anions generates a rich family of derivative bismuth and antimony halogenometalates, known and yet unknown, with very promising novel functional and tunable properties. As used herein, the term “metalate” refers to a class of chemical compounds containing anionic units of one or more metals M and one or more anions X, which can be isolated clusters, chains, layers, or complex three-dimensional structures. The common structural motif of complex bismuth halides is the bismuth halide octahedron [BiX₆]. By condensation of these octahedra—via shared X apexes, X-X edges, or X-X-X faces—anionic units range from discrete mono- to poly-nuclear species (0D), over various 1D chains and bands to very complex 2D layered sheets [10]. Currently, there have not been any prior examples in literature of a three-dimensionally all-corner connected network of [BiX₆] octahedra (perovskite type). The only 3D structured bismuth halide phase reported, Cu_{0.99}BiI₄, features a 3D-connected structure of edge-sharing [BiI₆]-octahedra with disordered partial occupancy on all the metal sites [13].

With the counter cations A=CH₃NH₃⁺ (MA) or NH₂(CH)NH₂⁺, the only organic cations for which lead halide salts APbX₃ adopt the perovskite structure type [14], 0D bismuth iodides A₃Bi₂I₉ with isolated clusters of face-sharing [BiI₆] octahedra are formed [15]. With smaller counter cations like K⁺ or Rb⁺, salts of analogous compositions A₃Bi₂I₉ crystallize with a layered structure type which can be described as a defect and distortion variant of the perovskite structure [16]. Certain aspects of the invention focus on the phases along with the all-inorganic analogue Cs₃Bi₂I₉ as well as the binary BiI₃. One significance of the invention lies in the fabrication of optoelectronic devices based on these and other related materials. Bismuth halide complex based optoelectronic devices have great commercial advantages. They do not contain toxic elements like the lead halide perovskites but have the same desirable properties. They can be fabricated by low temperature solution coating methods. The easy process and low energy cost is of obvious importance in manufacturing the devices.

An optoelectronic device can be selected from a photovoltaic device; a photodiode; a phototransistor; a photo detector; a light-emitting device; a light-emitting diode; a transistor; a solar cell and a laser.

In one aspect of the present invention, a photovoltaic (solar cell) device is provided. The bismuth halides may act as a light-absorbing, photo-sensitizing material, as well as a charge-transporting material in the solar cell device.

The solar cell devices described in this invention are different than “Grätzel solar cells” or “dye sensitized solar cells”, which comprise of a mesoporous layer of metal oxide nanoparticles (usually TiO₂), covered with a thin layer (or monolayer) of organic or inorganic dye that absorbs sunlight. The mesoporous oxide is immersed under an electrolyte solution or gel, typically an iodine-iodide redox system, and sandwiched between two electrodes [38, 39]. One of the overriding reasons for the lack of commercial uptake of dye sensitized solar cell is the liquid or gel nature of the redox couple used in the electrolyte, and chemical instability of the iodide/iodine redox couple. It is highly volatile and corrosive resulting in major limitations on both processing and long term stability, especially at elevated temperatures. It has been previously reported that the inorganic lead perovskite absorbers decayed rapidly in a liquid electrolyte system, and the dye sensitized solar cell dropped in performance after a few minutes [7].

In one aspect of the present invention, a solid state thin film optoelectronic device is provided. The optoelectronic device comprises a semiconducting active layer sandwiched in between a first electrode and a second electrode. The active layer comprises a material of the formula AₐB_{b}MₘXₓ, wherein A represents a monovalent inorganic cation, a monovalent organic cation or mixture of different monovalent organic or inorganic cations; B represents a divalent inorganic cation, a divalent organic cation or mixture of different divalent organic or inorganic cations; M is Bi³⁺ or Sb³⁺; X represents a monovalent halide anion, or mixture of different monovalent halide anions; a, b represent 0 or any positive numbers, m, x represent any positive numbers, and a+2b+3m=x.

In another aspect of the present invention, an optoelectronic device is provided. The optoelectronic device comprises an active layer sandwiched in between a first electrode and a second electrode. The active layer comprises a material of the formula AₐB_{b}MₘXₓ, wherein A and A′ are separately a monovalent inorganic cation, a monovalent organic cation or nothing; B is a divalent inorganic cation, a divalent organic cation or nothing; M is Bi³⁺ or Sb³⁺; X is a monovalent halide anion, a cyanide CN⁻ or a formate HCOO⁻. Furthermore, in one or more embodiments, the active layer comprises more than one monovalent halide anion X(e.g. BiI₃).

The optoelectronic device may further comprise a substrate, an first electrode deposited on the substrate, an optional electron conducting/hole blocking layer deposited either between the first electrode and the active layer, or between the active layer and the second electrode, and an optional hole conducting/electron blocking layer deposited either in between the first electrode and the active layer, or between the active layer and the second electrode. Thus, embodiments of the optoelectronic device may have a standard or inverted structure. In one or more embodiments, the optoelectronic device comprises a substrate, a first electrode deposited on the substrate, an electron conducting/hole blocking layer deposited between the first electrode and the active layer, and a hole conducting/electron blocking layer deposited between the active layer and the second electrode. In other embodiments, the optoelectronic device comprises a substrate, a first electrode deposited on the substrate, a hole conducting/electron blocking layer deposited between the first electrode and the active layer, and an electron conducting/hole blocking layer deposited between the active layer and the second electrode. Additionally, the optoelectronic device may further comprise a mesoporous electron conducting layer between the electron conducting/hole blocking layer and the active layer.

The term “halide” refers to an anion of a group 7 element, i.e., of a halogen. Typically, halide refers to a fluoride anion, a chloride anion, a bromide anion, an iodide anion or an astatide anion. The term “chalcogenide anion”, as used herein refers to an anion of group 6 element, i.e. of a chalcogen. Typically, chalcogenide refers to an oxide anion, a sulphide anion, a selenide anion or a telluride anion.

The term “mesoporous”, as used herein means that the pores in the porous structure are microscopic and have a size which is usefully measured in nanometers (nm). The mean pore size of the pores within a “mesoporous” structure may for instance be anywhere in the range of from 1 nm to 100 nm, or for instance from 2 nm to 50 nm. Individual pores may be different sizes and may be any shape.

The term “active layer”, as used herein, refers to a layer in the optoelectronic device which comprises materials that conduct the main function of the device. For example, an active layer in a solar cell device comprises materials that absorb light, which may then generate free charge carriers; and transfer charges to the opposite electrodes through optional charge transporting layers. An active layer in a light-emitting diode comprises materials that accept charge, both electrons and holes, which may subsequently recombine and emit light. An active layer in a field effect transistor comprises materials that conduct charges between the source and the drain electrode. The materials can be n-type (dominantly electron transporting) or p-type (dominantly hole transporting) or ambipolar semiconductors.

In one or more embodiments of the invention, the optoelectronic device comprises a glass substrate, an electron conducting/hole blocking layer deposited on the glass substrate, an active layer deposited on the electron conducting/hole blocking layer, a hole conducting/electron blocking layer deposited on the active layer, and a metal electrode deposited on the hole conducting/electron blocking layer. The glass substrate may be a pre-cut FTO or ITO-coated glass or quartz glass substrate. The active layer comprises a material of the formula AₐB_{b}MₘXₓ, wherein A represents a monovalent inorganic cation, a monovalent organic cation or mixture of different monovalent organic or inorganic cations; B represents a divalent inorganic cation, a divalent organic cation or mixture of different divalent organic or inorganic cations; M is Bi³⁺ or Sb³⁺; X represents a monovalent halide anion, or mixture of different monovalent halide anions; a, b represent 0 or any positive numbers, m, x represent any positive numbers, and a+2b+3m=x.

In some embodiments, the substrate is made of glass or plastic. The first and second electrodes are an anode and a cathode, and usually one or both of the anode and cathode is transparent to allow the ingress of light. The choice of the first and second electrodes of the optoelectronic devices of the present invention may depend on the structure type. In some embodiments, the first layer of the device is deposited onto the first electrode which comprises indium doped tin oxide (ITO), fluorine doped tin oxide (FTO), or high conductivity PEDOT:PSS, or composite of PEDOT:PSS with graphene or silver nanowire. In some embodiments, the second electrode comprises a metal, for instance calcium, aluminum, gold, silver, nickel, palladium or platinum.

In another aspect of the present invention, a method of forming an optoelectronic device is provided. The method comprises depositing an active layer between a first electrode and a second electrode. The active layer comprises a material of the formula AₐB_{b}MₘXₓ, wherein A represents a monovalent inorganic cation, a monovalent organic cation or mixture of different monovalent organic or inorganic cations; B represents a divalent inorganic cation, a divalent organic cation or mixture of different divalent organic or inorganic cations; M is Bi³⁺ or Sb³⁺; X represents a monovalent halide anion, or mixture of different monovalent halide anions; a, b represent 0 or any positive numbers, m, x represent any positive numbers, and a+2b+3m=x. The active layer may be deposited by drop-casting, spin-coating or vapor deposition.

In one or more embodiments, the method further comprises depositing the first electrode onto a substrate. An electron conducting/hole blocking layer is deposited between the active layer and one of the first or second electrode. For example, a dense layer of TiO₂ may be deposited by spin-coating. A hole conducting/electron blocking layer is deposited between the active layer and the other of the first or second electrode. Suitable electrodes include Au, Ag, Al Pt, Pd, and conductive transition metal oxides. In one or more embodiments, the method further comprises depositing a mesoporous electron conducting layer between the electron conducting/hole blocking layer and the active layer.

Illustrative thin film deposition methods include a spin coating method, a casting method, a microgravure coating method, a gravure coating method, a bar coating method, a roll coating method, a blade coating method, a wire bar coating method, a dip coating method, a spray coating method, a free span coating method, a dye coating method, a screen printing method, a flexo printing method, an offset printing method, an inkjet printing method, a dispenser printing method, a nozzle coating method and a capillary coating method, for forming a film from a solution.

Illustrative solvents to dissolve bismuth halides include but not limited to water, DMF, DMSO, DMAc, γ-butyrolactone, THF, 1,3-dioxane, acetonitrile and the combination thereof.

Illustrative transparent electrode materials for the optoelectronic device include binary or complex oxides, maybe partially indium or fluoride doped, such as (aluminum doped) SnO₂, ZnO, TiO₂ or ZrO₂, doped Al₂O₃, BaSnO₃, InGaO₃, SrGeO₃. In general, pure or doped transition metal or main group metal transparent oxides with electrons available for conduction may be used. Additionally, metal-free alternatives such as graphene materials or conductive (flexible polymers) such as PEDOT:PSS or electrodes of very thin metal films on flexible polymers like PET as described by C. Roldán-Carmora et al. [18] may also be used.

Nano to meso structured materials such as ordered nano-rods, tubes, spheres or other shapes of interesting aspect ratios of pristine or doped metal oxides, such as SnO₂, TiO₂, ZnO, ZrO₂, Al₂O₃, BaSnO₃, InGaO₃, and SrGeO₃ may be used. In one or more embodiments, the electron conducting layer can be selected from the group consisting of but not limited to TiO₂, ZnO, ZrO₂, Al₂O₃, BaSnO₃, InGaO₃, and SrGeO₃. Electron conducting layer can be an organic electron semiconductor such as fullerene C₆₀, C₇₀ and their derivatives, n-type organic small molecule, oligomer and polymer semiconductors, such as poly{[N,N′-bis(2-octyldodecyl)-naphthalene-1,4,5,8-bis(dicarboximide)-2,6-diyl]-alt-5,5′-(2,2′-bithiophene)} (P(NDI2OD-T2)).

In an aspect of the present invention, the active layer comprises a perovskite-related material of the formula AₐB_{b}MₘXₓ. In one or more embodiments, the active layer comprises a material selected from the group consisting of MX₃, AMX₄, A₃MX₆,A₃M₂X₉, perovskites, A₂A′MX₆ double perovskites, and Aₙ₊₁A′_{n/2}M_{n/2}X₃ₙ₊₁ Ruddlesden-Popper phases. In certain instances, the active layer is a bismuth halide selected from the group consisting of K₃Bi₂I₉, Rb₃Bi₂I₉, Cs₃Bi₂I₉, (CH₃NH₃)₃Bi₂I₉, (NH₂(CH)NH₂)₃Bi₂I₉, and (NH₃(CH₂)₂NH₃)₂Bi₂I₁₀. Furthermore, in various embodiments, the active layer contains a [MX₆] octahedra connected via shared apexes, edges or faces, and n is an integer less than or equal to 6. In one instance, the active layer is selected to have a bandgap no more than 2.1 eV.

In one or more embodiments, A and A′ are separately selected from the group consisting of H⁺, H₃O⁺, NH₄⁺, H₃NOH⁺, Li⁺, Na⁺, K⁺, Rb⁺, Cs⁺, Cu⁺, Ag⁺, BiO⁺, methylammonium CH₃NH₃⁺, ethylammonium (C₂H₅)NH₃⁺, alkylammonium, formamidinium NH₂(CH)NH₂⁺, guanidinium C(NH₂)₃⁺, imidazolium C₃N₂H₅⁺, hydrazinium H₂N—NH₃⁺ azetidinium (CH₂)₃NH₂⁺, dimethylammonium (CH₃)₂NH₂⁺, tetramethylammonium (CH₃)₄N⁺, phenylammonium C₆H₅NH₃⁺, arylammonium, and heteroarylammonium. In one or more embodiments, B is a divalent primary, secondary, tertiary, or quaternary organic ammonium cation with 1 to 100 carbons and 2 to 30 heteroatoms, wherein two of the heteroatoms are positively charged nitrogen atoms. In certain instances, B is selected from the group consisting of Mg²⁺, Ca²⁺, Sr²⁺, Ba²⁺, Ti²⁺, V²⁺, Ni²⁺, Cr²⁺, Co²⁺, Fe²⁺, Sn²⁺, Cu²⁺, Ag²⁺, Zn²⁺, Mn²⁺, NH₃CH₂CH₂NH₃²⁺, NH₃(CH₂)₆NH₃²⁺, NH₃(CH₂)₈NH₃²⁺ and NH₃C₆H₄NH₃²⁺.

The term “organic cation” refers to a cation comprising carbon. The cation may comprise further elements, for example, the cation may comprise hydrogen, nitrogen or oxygen. An aryl group is a substituted or unsubstituted, monocyclic or polycyclic aromatic group which typically contains from 4 to 30 carbon atoms in the ring portion. The term “heteroaryl” represents a monocyclic- or polycyclic aromatic ring comprising carbon atoms, hydrogen atoms, and one or more heteroatoms, independently selected from nitrogen, oxygen, sulfur, silicon, boron, phosphous, germanium.

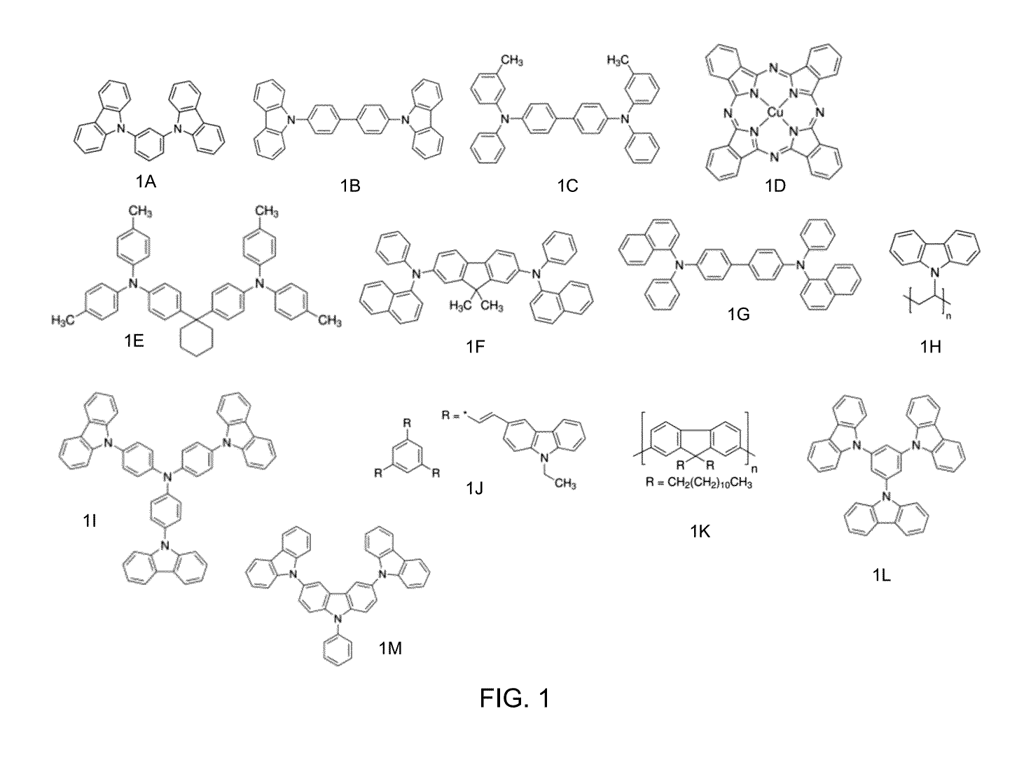

In further embodiments, the hole conducting layer is selected from but not limited to the group consisting of poly(3,4-ethylenedioxythiophene): polystyrene sulfonate (PEDOT:PSS), p-type organic small molecule semiconductors such as Spiro-MeOTAD, pentacene, biscarbazolylbenzene, oligomer semiconductors, polymer semiconductors such as PTAA, poly(3-hexylthiophene-2,5-diyl) (P3HT), donor-acceptor copolymer semiconductors such as PCPDTBT, PCDTBT [40], metal oxides such as VOₓ, NbOₓ, MoOₓ, WOₓ, NiOₓ, where x is less than 3, or other main group or transition metal oxides and a compound as shown in FIG. 1.

### EXAMPLES

### Example 1

### Synthesis

### Purchased Chemicals

For the preparation of the materials and for making optoelectronic devices the following starting materials were purchased: BiI₃ (99.999%, Strem Chemicals), NaI (99%, Strem Chemicals), KI (99.998%, Alfa Aesar), RbI (99.8%, Stem Chemicals), CsI (99.999%, Strem Chemicals), AgI (99%, Aldrich), CuI (99.5%, Aldrich). CH₃NH₂ 33% solution in absolute ethanol and HI 57% (99.95%) were purchased from Sigma-Aldrich, (NH₂—(CH)NH₂)(CH₃COO) (99%) Acros Organics, NH₂(CH₂CH₂)NH₂ (99%) Alfa Aesar. PTAA (Aldrich, Mₙ 7000-10000) and Spiro-MeOTAD (Aldrich, 99%).

### Other Starting Materials

(CH₃NH₃)I (MA)I, (NH₃CH₂CH₂NH₂)I₂ (EDA)I₂ and PyI were obtained as starting materials from the corresponding amines and HI following the procedure for making (MA)I given in [17]. Formamidinium iodide (FA)I was prepared by dissolving formamidinium acetate in a 2× molar excess of HI forming a light yellow solution. The mixture was refluxed for 10 minutes in an oil bath at 100° C. N₂ gas was then bubbled into liquid and the resulting stream was purged by passing it through a concentrated solution of NaOH. The yellow liquid was concentrated in vacuo then cooled overnight at 8° C. forming light yellow platelets. The yellow colored solution, indicating decomposition of (FA)I, was filtered and washed off with anhydrous diethyl ether yielding white crystals. The material was recrystallized from hot ethanol/water. The crystals were dried under vacuum and stored in N₂ atmosphere. ¹H NMR (25° C., 600 MHz, D₂O): δ ppm 7.85 (s, 1H, CH), melting of (FA)I occurs at 188° C.-192° C. in air.

Synthesis of A₃Bi₂I₉ (A=Rb (2), Cs (3), MA (4)), Single Crystals

In order to grow single crystals of complex bismuth halides suitable for single crystal X-ray diffraction, a solvothermal approach was applied. Fine powders of the starting materials AI and BiI₃ in a stoichiometric ratio of 3:2 were suspended in anhydrous ethanol and heated to 120° C. in a pressure vessel (23 mL digestion vessel with Teflon liner, purchased from Parr Instrument Company) for 6 hours and slowly cooled down to room temperature.

Typical amounts of starting materials suspended in 6 mL of ethanol were:
Rb₃Bi₂I₉ (2): RbI (210.4 mg, 0.99 mmol) with BiI₃ (389.6 mg, 0.66 mmol),
Cs₃Bi₂I₉ (3): CsI (238.8 mg, 0.92 mmol) with BiI₃ (361.2 mg, 0.61 mmol),
(MA)₃Bi₂I₉ (4): (MA)I (172.8 mg, 1.09 mmol) with BiI₃ (427.2 mg, 0.72 mmol).

Red crystals of up to 2 mm size for 2 were obtained. The phase identification and purity was confirmed by powder and single crystal X-ray diffraction. Reactions to target compounds with mixed alkali metal compositions such as RbNaBiI₆ were conducted in the same manner.

Synthesis of K₃Bi₂I₉ (1), Single Crystals

Crystalline K₃Bi₂I₉ was prepared following the protocol given in [10] by reacting KI (179.8 mg, 1.08 mmol) with BiI₃ (421.8 mg, 0.72 mmol) in a sealed fused silica ampoule. The starting materials were ground in an agate mortar under argon gas atmosphere in a glove box (<0.1 ppm H₂O and O₂) and were sealed under inert conditions in a fused silica ampoule (approx. 6 mL volume) while cooling the bottom of the tube in a liquid nitrogen bath and evacuating the tube to approx. 10⁻³ mbar. The ampoule was heated to 690° C. (heating rate 100° C./h, hold time 12 hours) and subsequently annealed at 350° C. (hold time 12 days, cooling rate 100° C./h). Small red crystals were collected from the inner ampoule walls and the analysis by single crystal diffraction confirmed the successful synthesis (determined unit cell, see Table 1). Reactions to target compounds with mixed alkali metal compositions such as RbNaBiI₆ were conducted in the same manner.

Synthesis of A₃Bi₂I₉ (A=K (1), Rb (2), Cs (3), MA (4)), Polycrystalline Samples

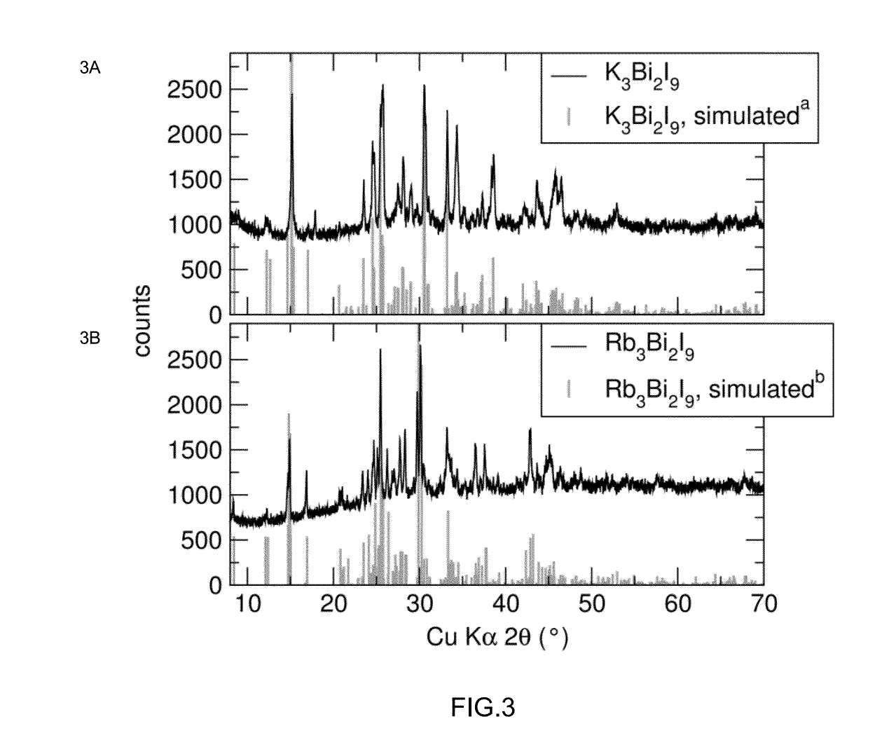

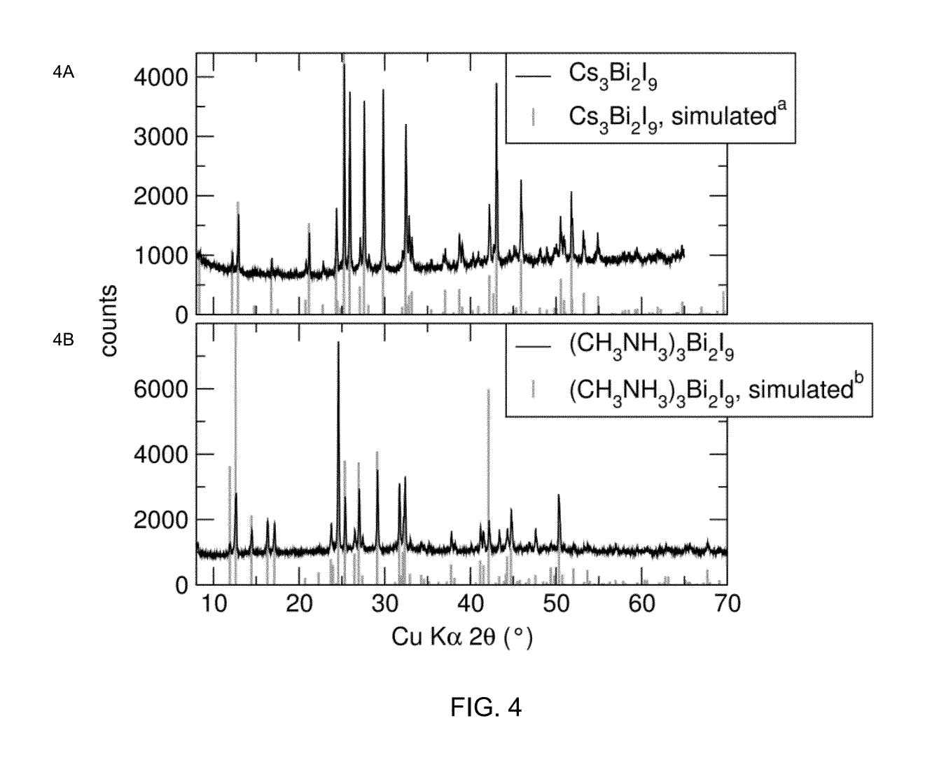

Pure powder samples of the iodides 1, 2, 3, and 4 were prepared by reacting stoichiometric amounts of the starting iodides (see above) in anhydrous acetonitrile (typically 3-4 mL for 600 mg starting materials) in air. After stirring for 6 hours red clear solutions were obtained for target compounds 1 and 2 while for 3 and 4, red precipitations formed under red solutions. Red powders of the target compounds (powder X-ray pattern, see FIGS. 3 and 4) were isolated in complete yields by removing the solvent under vacuum at room temperature. Compounds 1, 2, 3, and 4 are relatively stable when exposed to the atmosphere but the crystallinity of the samples deteriorated in moist air over the course of hours to weeks, while the salts deteriorated faster the smaller the counter cations are. Alternative solvents would be alcohols such as butanol at elevated temperatures or tetrahydrofuran.

Synthesis of (FA)₃Bi₂I₉ (5)

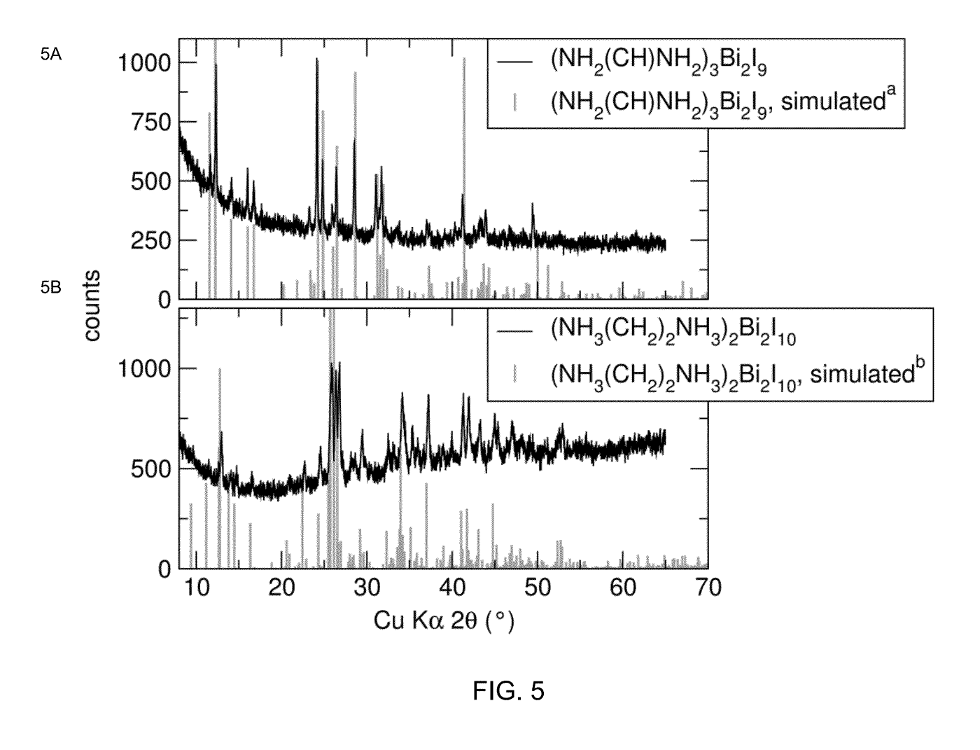

In a glove box (<1 ppm H₂O and O₂) with nitrogen atmosphere (FA)I and BiI₃ were mixed in a stoichiometric ratio, e.g. (FA)I (187.5 mg, 1.09 mmol) and BiI₃ (428.6 mg, 0.73 mmol), in acetonitrile stirred for 3 hours at room temperature. The resulting red precipitation was separated from the red solution by filtration and washed with a little acetonitrile (yield approx. 60%) and dried under vacuum (powder X-ray diffraction, see FIG. 5). Single crystals of 5 were grown from a solution of the starting iodides in a stoichiometric ratio in DMF obtained after 3 hours of stirring at room temperature. The red solution was allowed to slowly evaporate at room temperature on a glass slide. Bright red single crystals were obtained after 3 days (determined unit cell, see Table 1). When exposed to the atmosphere, 5 decomposes within hours while turning brownish, crystals were stable under silicon oil for several days.

Synthesis of (EDA)₂Bi₂I₁₀ (6)

In a typical synthesis of polycrystalline 6, (EDA)I₂ (104.7 mg, 0.33 mmol), BiI₃ (195.3 mg, 0.33 mmol) were suspended in acetonitrile and stirred for 4 hours. The resulting red precipitation was either separated from the red solution by filtration or the product was obtained by removal of the solvent under vacuum at room temperature. The phase purity was confirmed by X-ray diffraction. Red single crystals of 6 were grown from the red solution of the starting iodides in H₂O with a drop of HI (57% in water), placed on a glass slide through solvent evaporation over the course of three days (determined unit cell, see Table 1).

Synthesis of Py₃Bi₂I₉

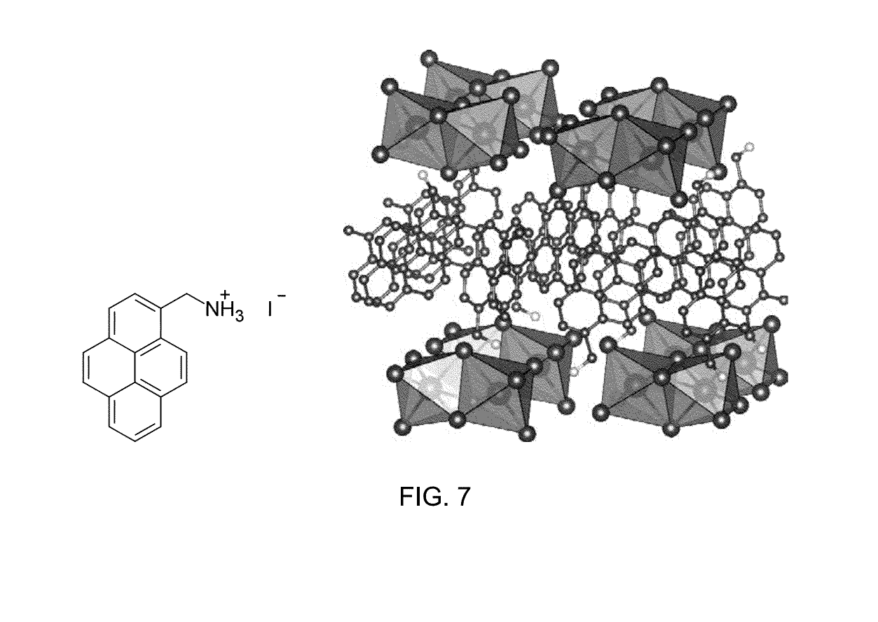

FIG. 7 shows the chemical structure of 1-pyrenemethylammonium iodide and crystal structure of Py₃Bi₂I₉. Py₃Bi₂I₉ was prepared in crystal form from a solution reaction, where 1-pyrenemethylammonium iodide (PyI) and bismuth iodide were combined in 1:1 ratio in acetonitrile, heated to 100° C., 6 hours, and slow cooled over 2 days. The material is orange in bulk and deep red in single crystal form. Additionally, based on this structure, by modifying this pyrene to a di-methylammonium pyrene we can condense the structure even further and promote greater conjugation between the functional organics. FIG. 7 shows the crystal structure of the material obtained when we incorporated 1-pyrenemethylammonium with bismuth iodide. The 1-pyrenemethylammonium bismuth iodide obtained possesses 0D face sharing Bi₂I₉³⁻ octahedra creating pseudo layers, with disordered yet partially pi-pi stacked pyrene molecules lying in the interlayer voids. Crystal parameters of Py₃Bi₂I₉ is listed in Table 2.

Synthesis of AgBiI₄ and Ag₃BiI₆

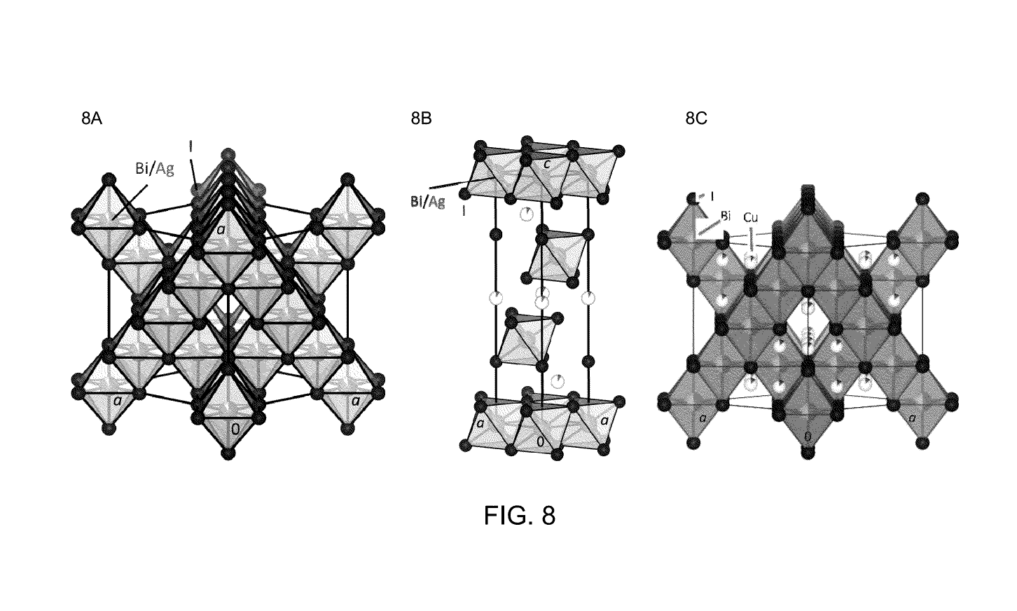

As the black ABiI₄ phases are to our knowledge the only reported examples of bismuth halides with a 3D network structure (and thus a small band gap and potentially higher charge carrier mobilities). We tried to reproduce the preparation of the reported phases A_{1-δ}Bi_{1+δ/3}I₄ (A=Ag [41] or Cu [42], δ is a small number between 0 to 1, e. g. 0.01 representing vacancies or defects in the non-perfect lattice, see FIG. 8). When comparing the closely related crystal structures published for Cu_{0.99}BiI₄ (FIG. 8C) and Ag_{0.82}BiI₄ (FIG. 8A) it is interesting to note that the BiI₆ network is identical. However, the smaller Cu⁺ cation occupies tetrahedral voids between the BiI₆ octahedra, while the larger Ag⁺ shares the underoccupied Bi sites. Those structures were described only once, each by a different group and were determined by single crystal Xray diffraction where it can be a challenge to refine different heavy atoms on one site. We are working to reproduce the synthesis of those materials also in order to verify the crystal structure by using modern (neutron) diffraction techniques. The first attempt of reproducing the solvothermal preparation of Ag_{1-δ}Bi_{1+δ/3}I₄ following the protocol given by Oldag and coworkers [41] yielded only a trace of the target material along with unreacted starting materials and a minor phase of unknown compositions. Curiously, by Oldag et al. the reaction of the starting materials AgI to BiI₃ in a 0.8:2 ratio yielded Ag_{1-δ}Bi_{1+δ/3}I₄ while a ratio of 1:1 gave crystals of Ag_{3-3δ}Bi_{1+δ}I₆, potentially indicating impure starting materials.

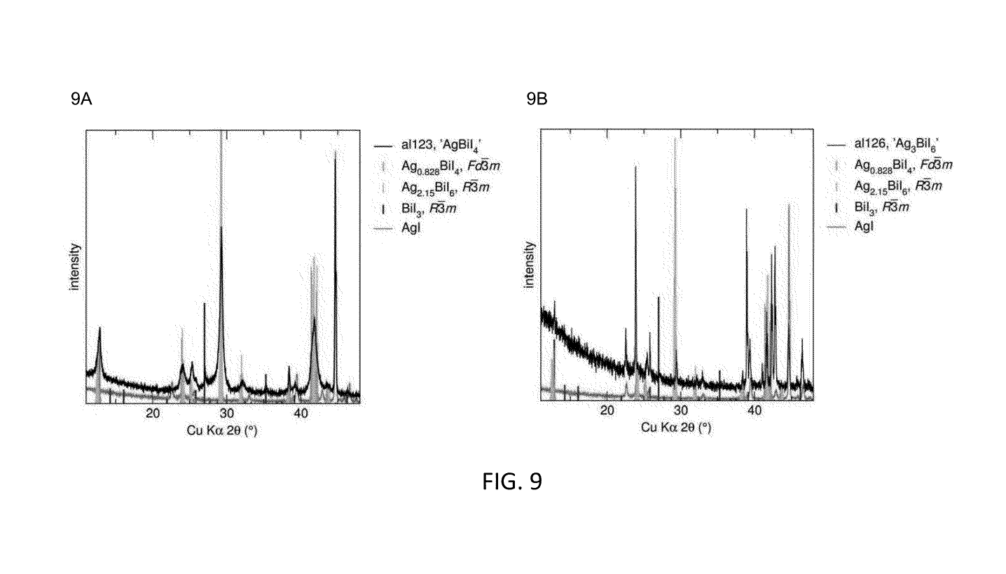

In our preparation, AgBiI₄ and Ag₃BiI₆ powder were prepared by high energy ball-milling of the starting iodides AgI and BiI₃ in a 1:1 ratio at RT for 10 minutes, which yielded a phase mixture with the starting materials still present but a majority of complex silver bismuth iodides (FIG. 9). Around the strong peak at 42° in 2Θ (stemming from the family of symmetry related {440} reflections), the differences of the diffraction patterns of Ag_{1-δ}Bi_{1+δ/3}I₄ and Ag_{3-3δ}Bi_{1+δ}I₆ are obvious: Ag_{1-δ}Bi_{1+δ/3}I₄ displays only one peak, while Ag_{3-3δ}Bi_{1+δ}I₆ features two peaks shifted to higher and lower 2Θ values. The broadening of the observed peak around 42° indicates the presence of both phases in our sample. Interestingly our solvothermal attempt of making Ag₃BiI₆, using a 1:1 ratio of starting iodides as given in [41], seemed to have led to the formation of the complex silver bismuth iodides Ag_{1-δ}Bi_{1+δ/3}I₄/Ag_{3-3δ}Bi_{1+δ}I₆ in larger fraction as for the 0.8:2 ratio. Still, they are only minor phases along with unreacted starting materials and one or more unknown residual phases (FIG. 9). Single crystals of Ag_{1-δ}Bi_{1+δ/3}I₄ and Ag_{3-3δ}Bi_{1+δ}I₆ were grown solvothermally in ethanol (FIG. 8).

Non-stoichiometric compounds such as the above silver bismuth iodides and copper bismuth iodides are common in solid inorganic compounds, which have elemental composition whose proportions cannot be represented by integers. Most often, in such materials, some small percentage of atoms is missing or too many atoms are packed into an otherwise perfect lattice work. Since the solids are still overall electrically neutral, the defect is compensated by a change in the charge of other atoms in the solid, either by changing their oxidation state, or by replacing them with atoms of different elements with a different charge. This vacancies or defects filled non-perfect lattice structures lead to lower overall free energy of the crystals. The compound stability in ambient atmosphere has been monitored by PXRD on as-prepared polycrystalline powder samples. With increasing size of the counter cation, the salts kept well for hours (K₃Bi₂I₉) to months (Cs₃Bi₂I₉) in ambient air, which is considerably longer than the extremely oxidation sensitive Sn²⁺ iodides or the moisture sensitive Pb²⁺ iodides would withstand.

Our preliminary studies have confirmed that phase widths of mixed counter cations K—Rb, Rb—Cs, K—Cs exist in the A₃Bi₂I₉ phases. By taking into account not only the counter cation, but also the variability of the central metal and halide, this rich family of compounds offers a large variety of new interesting phases with tunable properties.

### Example 2

### Typical Solar Cell Device Fabrication

Step 1) Pre-cut FTO or ITO-coated glass (1.5 cm×1.5 cm, 15 Ω/sq.; Thin Film Devices) or quartz glass substrates were sequentially sonicated in acetone, isopropyl alcohol, and deionized water for 10 min each. The substrates were then exposed to UV-ozone for 10 min to clean the surface.

Step 2) A dense layer of TiO₂ was deposited by spin-coating a solution prepared by dropping 0.035 mL 2M HCl in 2.53 mL ethanol slowly into a solution of Ti(OiPr)₄ (0.369 mL in 2.53 mL ethanol) and filtering with a 0.45 μm filter. The solvent was evaporated from the coated slides at 100° C. for 5 mins on a hotplate and the resulting film was removed from an approximately 0.2 cm wide strip along one edge with a cotton tip. After sintering (RT to 500° C. in 20 mins, hold at 500° C. for 30 mins) the film thickness was determined to be approximately 50-80 nm by scanning electron microscopy.

Step 3) An optional layer of meso-porous TiO₂ was cast onto the dense titania layer from a suspension of TiO₂ particles made by diluting the commercial 18NRT paste (Dysol) with ethanol (2:7 w/w, stirred for 1 h) by spin-coating at various spinning rates. The slides were then dried at 120° C. for 5 mins, as before, one edge of the film was removed (with a carbon tweezers tip) and the slides were tempered (RT to 500° C. in 20 mins, hold at 500° C. for 15 mins). The film thickness was determined to be approximately 200-450 nm when a spin rate of 2000-4000 rpm was used by scanning electron microscopy.

Step 4) The bismuth halide films were obtained by drop-casting or spin-coating from solution, different concentrations used) either on top of the mesoporous titania layer or directly on the dense titania layer. The iodides show solubility in a variety of solvents such as water, DMF, DMSO, DMAc, γ-butyrolactone, THF, 1,3-dioxane, acetonitrile are possible. A sequential deposition of the two different metal iodide precursors (e. g. KI and BiI₃) is possible for the complex iodides. Vapor deposition of the active layer is another possibility.

Step 5) As a hole conducting and electron blocking layer, the following options were tested: a) A solution of PTAA (Mw=17,500 g/mol) in toluene (15 mg/l mL) with 0.0136 mL Li-TFSI/acetonitrile (28.3 mg/l mL) and 0.0068 mL 4-tert-butyl-pyridine was spin-coated. b) A solution of spiro-MeOTAD (0.025 mL) 68 mM in chlorobenzene with Li-TFSI (9 mM) and 4-tert-butyl-pyridine (55 mM) was stirred overnight and films were cast by spin-coating. c) A solution of PIDT-2FBT in chlorobenzene (15 mg/l mL) with 0.0136 mL Li-TFSI/acetonitrile (28.3 mg/l mL) and 0.0068 mL 4-tert-butyl-pyridine was spin-coated.

Step 6) Gold back electrodes were evaporated with a film thickness of 80 nm. Other metals like Ag, Pt, Pd, or conductive transition metal oxides could be alternatives.

### Alternatives for the Different Functional Layers in the Above Protocol

Step 1) Other transparent electrode materials for solar cell devices are binary or complex oxides, maybe partially fluoride doped, such as (aluminium doped) SnO₂, ZnO, TiO₂ or ZrO₂, doped Al₂O₃, BaSnO₃, InGaO₃, SrGeO₃, in general materials with 4s or 5s electrons available for conduction. Metal-free alternatives like graphene materials or conductive (flexible) polymers or electrodes of very thin metal films on flexible polymers like PET as described by C. Roldán-Carmora et al. [18].

Step 2) and 3) Instead of a dense layer and/or mesoporous layer of TiO₂, other electron conductive oxides could be applied. Also nano to meso structured materials such as ordered nano-rods, tubes, spheres or other shapes of interesting aspect ratios of pristine or doped metal oxides such as SnO₂, ZnO, ZrO₂, Al₂O₃, BaSnO₃, InGaO₃, SrGeO₃ (and as listed in Step 1), an organic electron semiconductor such as fullerene C₆₀, C₇₀ and their derivatives, n-type organic small molecule, oligomer and polymer semiconductors, such as poly {[N,N′-bis(2-octyldodecyl)-naphthalene-1, 4,5,8-bis(dicarboximide)-2,6-diyl]-alt-5,5′-(2,2′-bithiophene)} (P(NDI2OD-T2)) could be used to improve device performance

Step 4) The active absorber layer can consist of a variety of perovskite-related materials:

AₐB_{b}MₘXₓ, containing [MX₆] octahedra connected via shared apexes, edges or faces;
e. g. MX₃,
   A₃MX₆,
   AMX₄,
   A₃M₂X₉, perovskites,
   A₂A′MX₆ double perovskites,
   Aₙ₊₁A′_{n/2}M_{n/2}X₃ₙ₊₁ Ruddlesden-Popper phases,
   M and X must be present in compounds;

with
A, A′ being a monovalent inorganic cation, such as H⁺, H₃O⁺, NH₄⁺, H₃NOH⁺, Li⁺, Na⁺, K⁺, Rb⁺, Cs⁺, Cu⁺, Ag⁺, BiO⁺ and/or a monovalent organic cation such as methylammonium CH₃NH₃⁺, ethylammonium (C₂H₅)NH₃⁺, or other alkylammonium, formamidinium NH₂(CH)NH₂⁺, guanidinium C(NH₂)₃⁺, imidazolium C₃N₂H₅⁺, hydrazinium H₂N—NH₃⁺ azetidinium (CH₂)₃NH₂⁺, dimethylammonium (CH₃)₂NH₂⁺, tetramethylammonium (CH₃)₄N⁺, phenylammonium C₆H₅NH₃⁺, or other arylammonium and heteroarylammonium;
B being a divalent inorganic cation, such as Mg²⁺, Ca²⁺, Sr²⁺, Ba²⁺, Ti²⁺, V²⁺, Ni²⁺, Cr²⁺, Co²⁺, Fe²⁺, Sn²⁺, Cu²⁺, Ag²⁺, Zn²⁺, Mn²⁺, and/or a divalent primary, secondary, tertiary, or quaternary organic ammonium cation with 1 to 100 carbons and 2 to 30 heteroatoms two of which being positively charged nitrogen atoms (e. g. ethylenediammonium H₃N(CH₂)₂NH₃²⁺). Illustrative examples of the divalent organic cations include but are not limited to the following: NH₃CH₂CH₂NH₃²⁺, NH₃(CH₂)₆NH₃²⁺, NH₃(CH₂)₈NH₃²⁺, NH₃C₆H₄NH₃²⁺;
M being Bi³⁺ or Sb³⁺; and
X being a monovalent halide anion or a cyanide CN⁻ or a formate HCOO⁻;

Step 5) Other hole transport materials can be the polymers PEDOT:PSS or P3HT or other organic materials with low-lying highest occupied molecular orbitals (HOMOs) such as biscarbazolylbenzene in order to improve the open circuit voltage of solar cells with the proposed absorber materials (with low valence band states). Illustrative organic materials are displayed in FIG. 1. Alternatively, inorganic materials such as VOₓ, NbOₓ, MoOₓ, WOₓ, or NiOₓ (x<3), which are promising candidates for efficient hole transport could be used, potentially offering lower cost and higher ultraviolet radiation and atmospheric stability than organic compounds. Y. Zhao et al. have recently reported effective hole extraction by the application of MoOₓ and aluminium as selective hole contact for (MA)PbI₃ based solar cells [19].

Step 6) As back electrodes, instead of Au, other metals such as Ag, Al, Pd, Pt, oxides or suitable polymers could be used.

### Example 3

### Instruments and Software

Laboratory X-ray diffraction patterns were acquired using a Philips X′Pert diffractometer with Cu Kα radiation and an X'Celerator PSD detector on powder samples spread on a silicon wafer. Single crystal X-ray data was collected using a Bruker KAPPA APEX II X-ray diffractometer Bruker 4-axis diffractometer equipped with a APEX II CCD detector and a fine focus sealed tube Mo X-ray source with a TRIUMPH monochromator. Data collection and cell parameter determination were conducted using the SMART program. The solution and refinement of the crystal structures was performed using the SHELXS-97 [20] and SHELXL-97 [21] software, respectively. Crystal structures were visualized using the software VESTA [22].

UV-Vis spectra were recorded using a Shimadzu UV-3600 UV-Vis NIR spectrophotometer equipped with a double monochromator and three detectors; PMT (photomultiplier tube) for ultraviolet and visible regions, PbS for NIR region, and an InGaAs detector for visible to NIR region transition. Diffuse reflexion measurements of powder samples were conducted on samples mixed with a BaSO₄ in a 1:10 mass ratio in an agate mortar and packed densely into the sample holder.

¹H NMR spectra were recorded on a Varian VNMRS 600 MHz spectrometer in D₂O with 4,4-dimethyl-4-silapentane-1-sulfonic acid as an internal standard.

Optical microscopy photographs were recorded using a Nikon eclipse E600 microscope and a Panasonic Lumix DMC-LX7 digital camera.

Scanning electron microscopy (SEM) was conducted using a FEI XL40 Sirion FEG Digital Scanning Microscope equipped with a high stability Schottky field emission gun.

X-ray photoelectron spectroscopy (XPS) measurements were recorded using a Kratos Axis Ultra system. The instrument's ultraviolet source was used for ultraviolet photoelectron spectroscopy (UPS) studies of the valence bands. Samples were prepared by drop-casting films (some in a nitrogen filled glove box (<1 ppm H₂O and O₂)) on highly doped silicon substrates on which gold has been evaporated (100 nm).

### Example 4

### Syntheses

While the synthesis and some structural and optoelectronic properties of the compounds BiI₃, A₃Bi₂I₉ (A=K, Rb, Cs, CH₃NH₃) [15, 16] and (NH₂(CH)NH₂)₃Bi₂I₉ [28] have been reported previously, there was yet no systematic study of the correlations between crystal chemistry, electronic structure and optoelectronic properties of these materials. Especially, the only report of the application of a bismuth iodide in a solar cell device is describes using BiI₃ as a hole transporting material, not as a photovoltaic absorber or electron transport material [11]. Formamidinium bismuth iodide (NH₂(CH)NH₂)₃Bi₂I₉ (5) is a novel compound. Compared to previously described syntheses, some of which are using high temperature and long reaction times, [16a, 16b] we provide a great facilitation of making complex bismuth iodides in bulk by applying one-step and complete-yield reactions in low-cost and non-toxic organic solvents at room temperature. In contrast to related moisture-sensitive lead halide perovskites and the air-sensitive tin halide perovskites, the bismuth based materials are more stable when exposed to water and atmosphere thus offering great advantages for potential device integration.

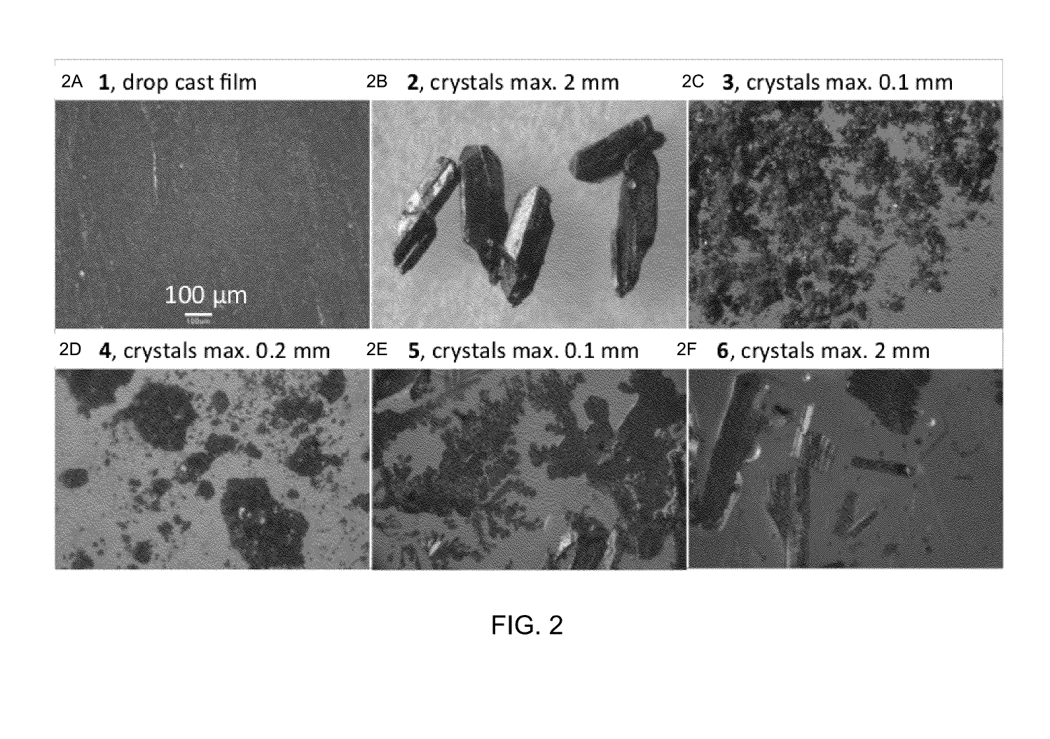

FIG. 2 displays optical microscopy photographs of A₃Bi₂I₉ and (NH₂(CH)NH₂)₃Bi₂I₉ compounds illustrating the facile growth of crystals from solutions under mild solvothermal conditions or at room temperature. The band gaps of these orange-red compounds are obviously not in the optimal range for maximal PCE in a single junction device.

### Phase Analysis and Crystal Structures

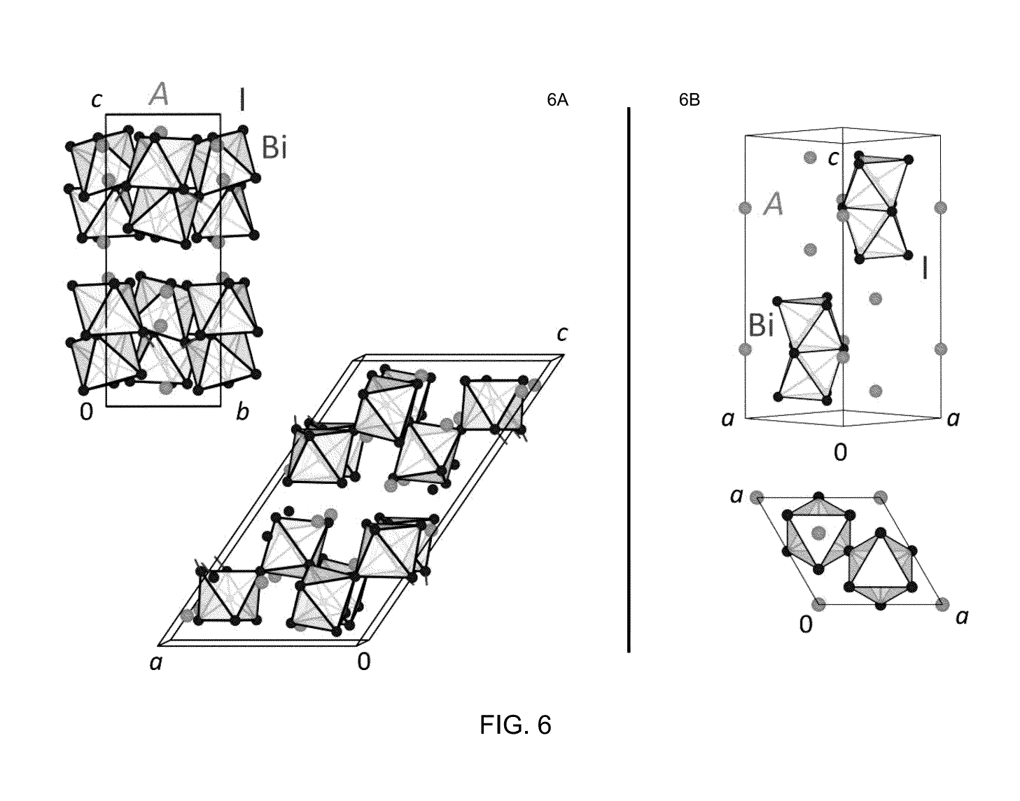

The phase purity of the complex bismuth iodides was confirmed by powder X-ray crystallography (FIGS. 3-5). For both the solvothermal and the ambient condition synthesis route, quite phase pure samples could be obtained as shows the good agreement between the experimental diffraction patterns and the simulated patterns from single crystal data. It is obvious from the diffraction patterns that for A₃Bi₂I₉, the compounds with A=K (1), Rb (2) (and also with A=Cs (3), CH₃NH₃ (4), NH₂(CH)NH₂ (5)) structurally closely related. By single crystal X-ray diffraction, the structures of the salts were (re)evaluated (Table 1). The two crystal structure types of the A₃Bi₂I₉ compounds are shown in FIG. 6. Compounds 1 and 2 crystallize with a monoclinic structure featuring corrugated 2D layers of corner-sharing [BiI₆]-octahedra, while the structures of 3, 4, and 5 contain isolated units of face-sharing [BiI₆]-octahedra. Interestingly, there is a very close relationship between the layered structure type and the perovskite structure. The formula of the monoclinic compound can be written A₃M₂□I₉ being equal to an ordered defect triple perovskite with three times the unit cell of perovskite, A₃M₃I₉, in which one third of the metal sites M remain unoccupied (symbolized by □). We propose that materials of the A₃M₂□I₉ structure type could be tuned towards being effective photovoltaic absorbers, with potentially a higher carrier mobility and a smaller band gap than the pristine compounds 1 and 2: Those changes in optoelectronic properties could be expected if the introduction of a monovalent cation such as Li⁺ or Na⁺ on the Bi³⁺ site was successful, especially if the two metals were disordered giving rise to Bi—I—Bi arrangements. In the crystal structures of the hybrid salts 4 and 5, the organic counter cations are heavily disordered and the atomic positions could not be refined. At low temperatures (approximately 145 K for 4, 120 K for 5) a decrease of the spacing of the reflections in the reciprocal space was observed, indicating a phase transformation. It can be assumed that an ordering of the counter cations occurs at low temperatures. In the crystal structure of (NH₃(CH₂)₂NH₃)₂Bi₂I₁₀ (6), isolated pairs of edge-sharing octahedra ([Bi₂I₁₀]⁴⁻) are coordinated via dipole-dipole interactions of ammonium cations and the complex metal iodide anions via N—H—I contacts.

Table 1 shows the crystallographic parameters, number of formula units per unit cell Z, unit cell dimensions a, b, c (Å), and β (°) and volume per formula unit V_{FU} (Å³), determined from single crystal X-ray experiments at room temperature for A₃Bi₂I₉ (A=K (1), Rb (2), Cs (3), CH₃NH₃ (4), (NH₂(CH)NH₂) (5)), and (NH₃(CH)₂NH₃)₂Bi₂I₁₀ (6).

### UV-Vis and DFT Calculations

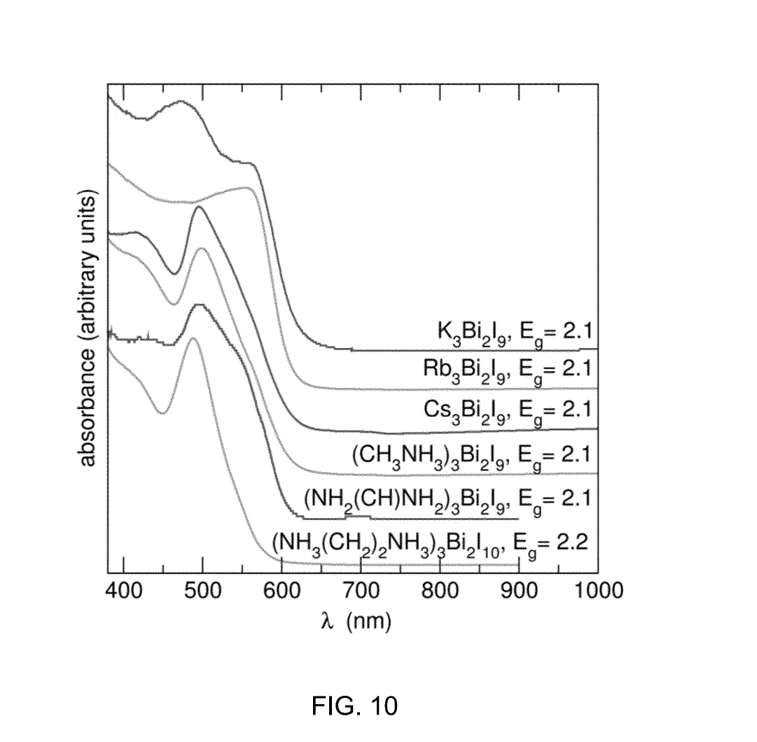

UV-Vis diffuse reflection spectra were recorded on powder samples of the complex bismuth iodides which were intimately mixed with an excess of BaSO₄ (FIG. 10). The reflection intensity was converted into absorbance by a Kubelka-Munch transformation and the band gap values were determined by a Tauc plot assuming direct band gaps for the complex bismuth iodides and an indirect band gap for BiI₃. The band gap values for all six compounds are close to 2.1 eV. Thus, the connectivity mode of the bismuth iodide octahedra-corner-sharing in 2D layers, face-sharing or edge-sharing in isolated dimers—does not seem to strongly affect the band gap energy. This observation is in accordance with the band gap energies and the nature of the bands in density of states (DOS) around the Fermi level as a result of DFT calculations for these compounds. The valence band maximum (VBM) consists of I(p) states and Bi(s) states whereas the main contribution to the conduction band minimum (CBM) comes from Bi(p) states. The fact that Bi states contribute both to the VBM and the CBM gives rise to an intra-atomic character of the optical transition. Therefore, the observation of the same energy band gap for complex bismuth iodides with different counter cations or structure types is comprehensible. The band gap of the layered polymorph of Cs₃Sb₂I₉ of around 2 eV indicates that the variation of the central metal from Bi to Sb also does not have a strong impact on the magnitude of the gap. [44] Due to the considerable effects of spin-orbit coupling on the electronic structure of heavy metals and the functional used here is known to not reproduce the band gap energies well, more suitable computational schemes have to be applied in order to better describe these systems.

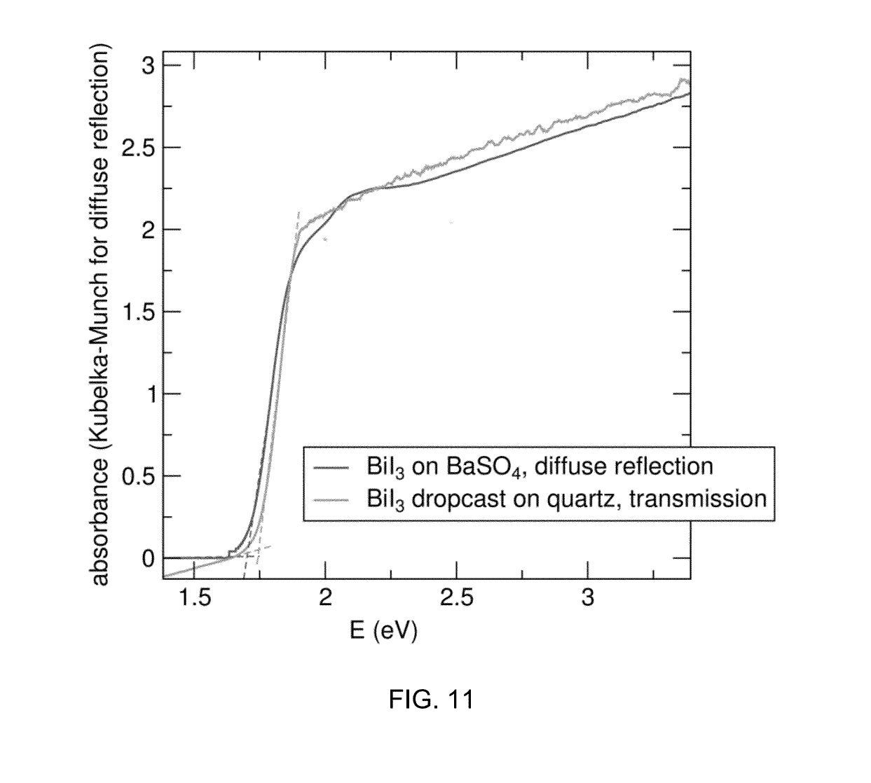

For BiI₃, in addition to the diffuse reflection measurement, transmission spectra were recorded on films drop-cast on quartz slides as a comparison experiment (FIG. 11). In both cases, the band gap was determined to be 1.7 eV.

### SEM

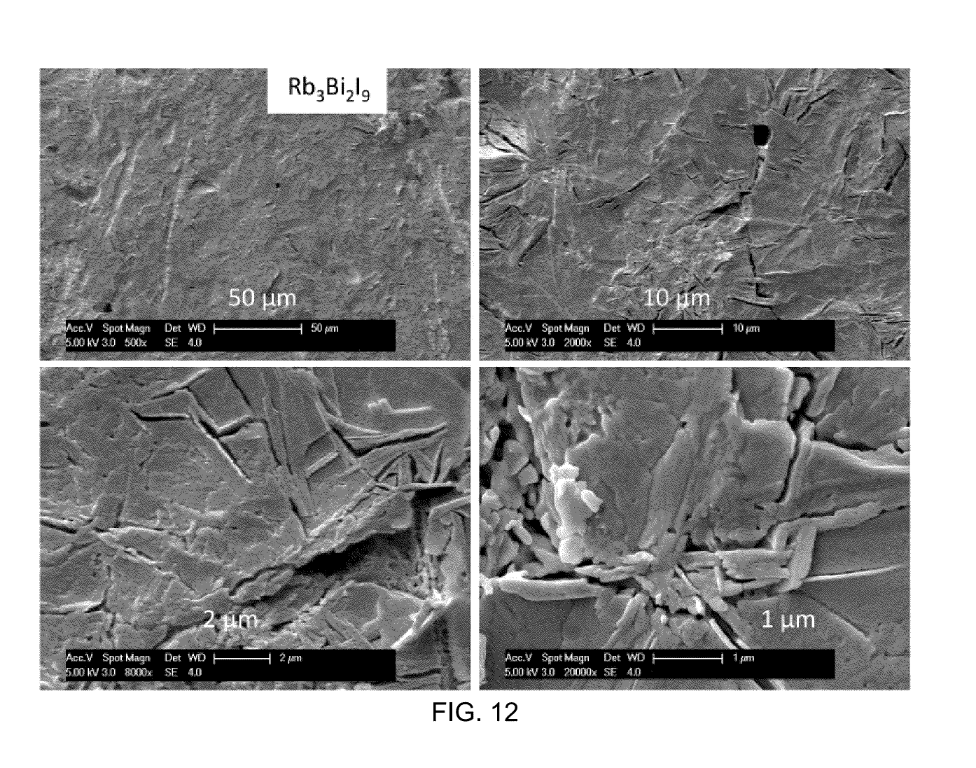

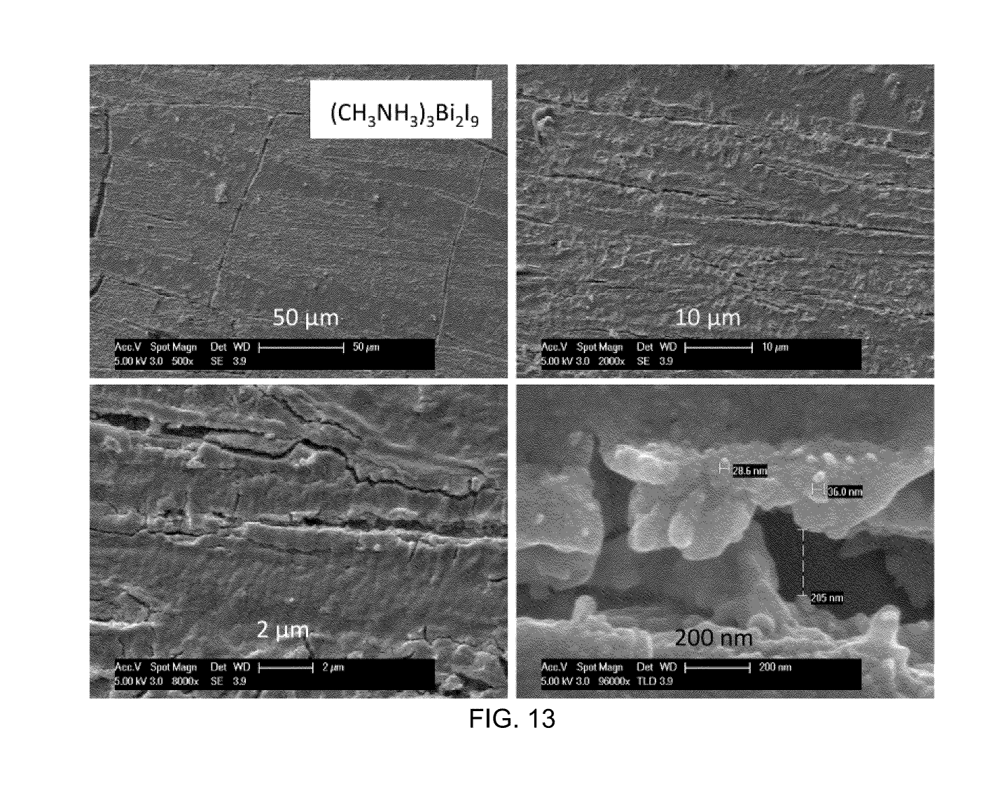

Scanning electron microscope images of 2 and 4 are shown in FIGS. 12 and 13. The lamellar crystal growth of the layered compound 2 can be easily seen. Spin-coating or doctor-blading could offer the advantage of faster nucleation and crystallization and thus smaller crystallite sizes.

### Example 5

### XPS

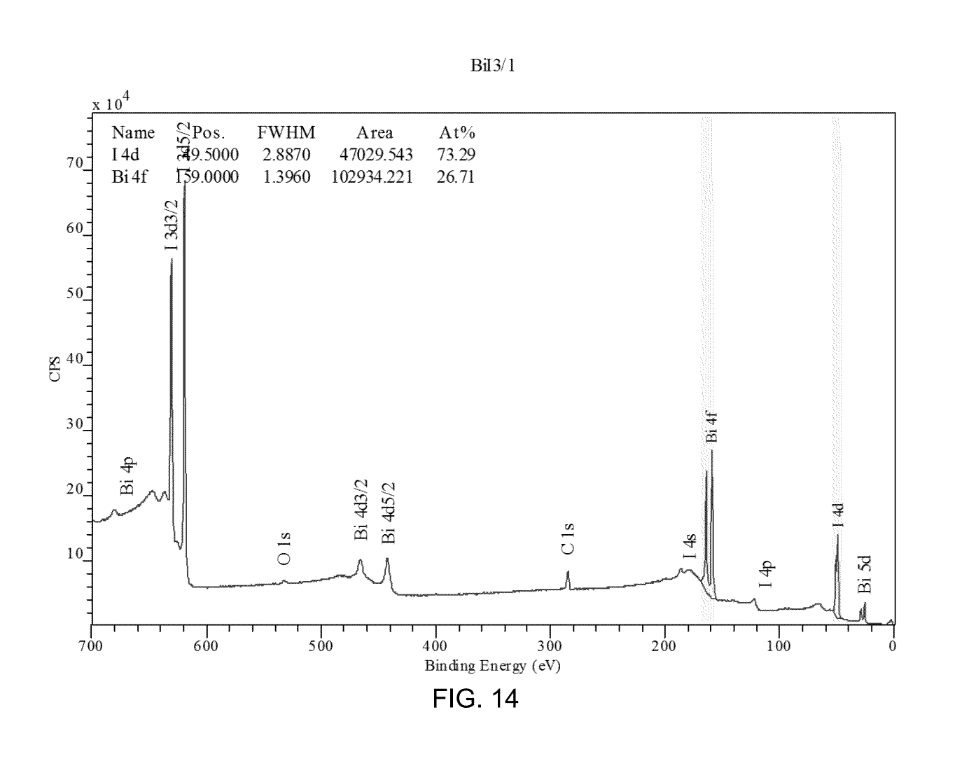

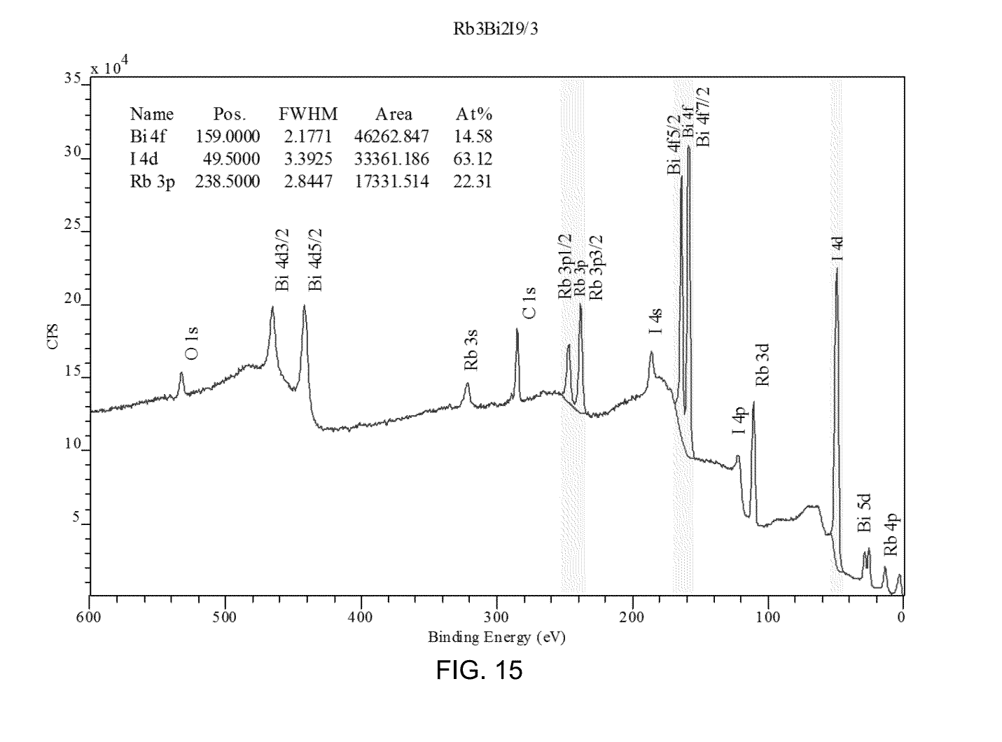

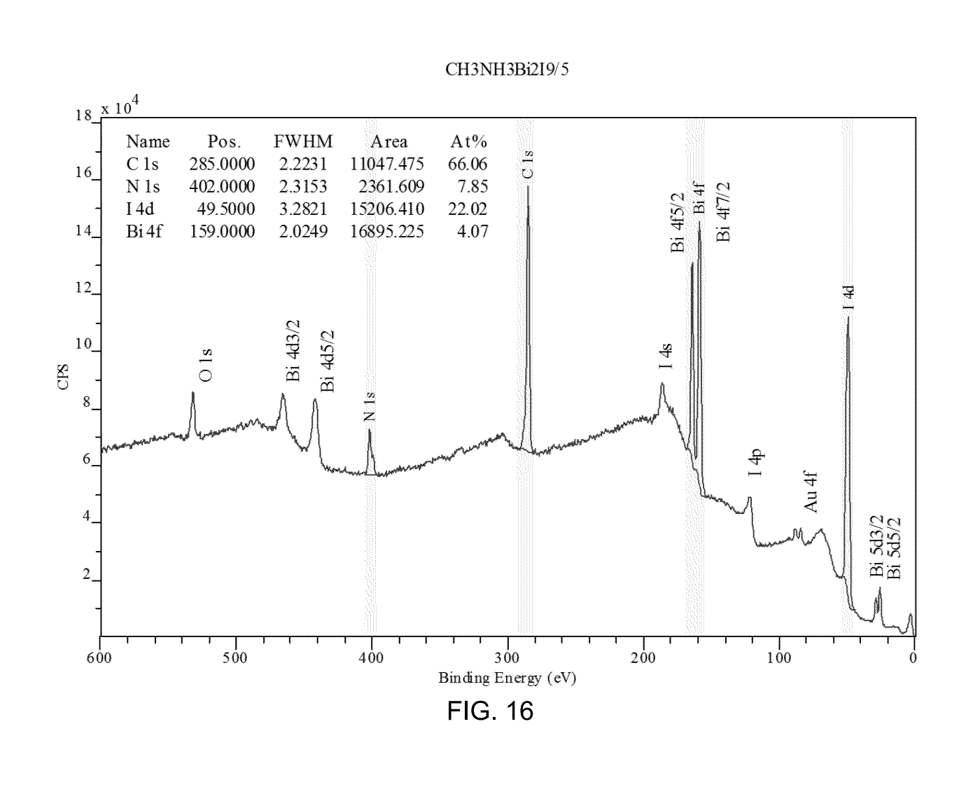

In order to analyze the surface elemental composition and the valence band positions of bismuth iodide films prepared in air, XPS spectra were recorded (FIGS. 14-16). All the compositions derived from the XPS data were close to the expected atom ratios disregarding oxygen and carbon impurities from sample preparation. For BiI₃, the experimental element rations were 27% Bi and 73% I versus the expected 25% Bi and 75% I. For the (CH₃NH₃)₃Bi₂I₉ (3), ignoring the carbon peak which is higher than expected due to carbon contamination, as well as the oxygen peak, the experimental atomic composition matches the expected as well, with 23% N, 12% Bi, and 65% I versus the expected 21% N, 14% Bi, and 64% I. Accordingly, for Rb₃Bi₂I₉ (2) the determined atomic composition of 22% Rb, 15% Bi, and 63% I was also close to the expected composition of 21% Rb, 14% Bi, and 64% I. XPS and UPS spectra were recorded a thin film of K₃Bi₂I₉ (1) prepared in a glove box under nitrogen. Even after the transfer to the instrument under N₂ atmosphere, low oxygen and carbon impurities are observed. The composition derived from the XPS data is K_{3.2}Bi_{2.0}I_{9.8} which is in good agreement with the nominal composition.

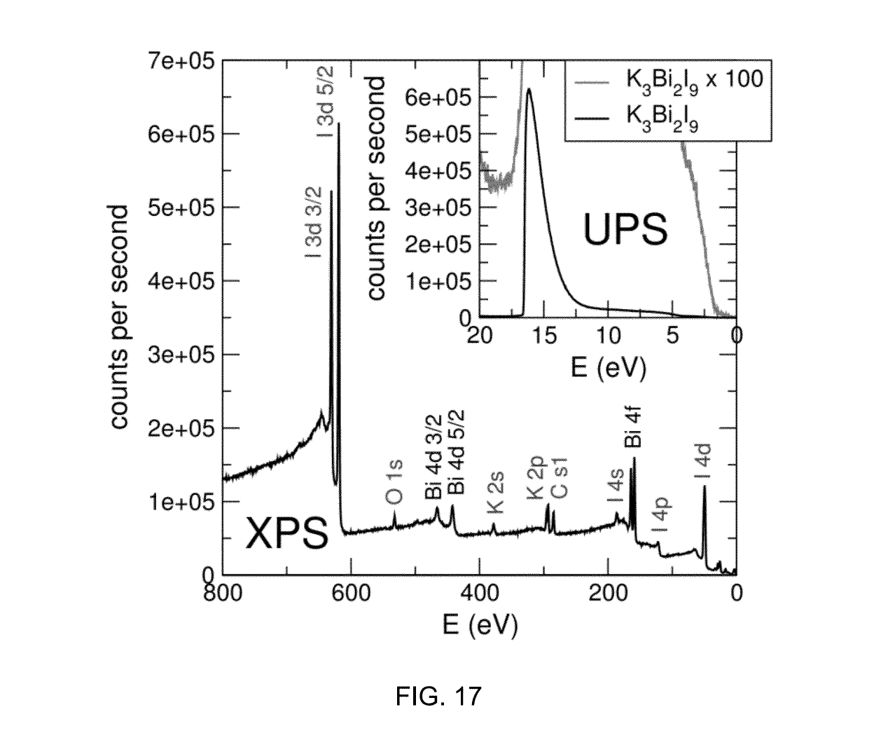

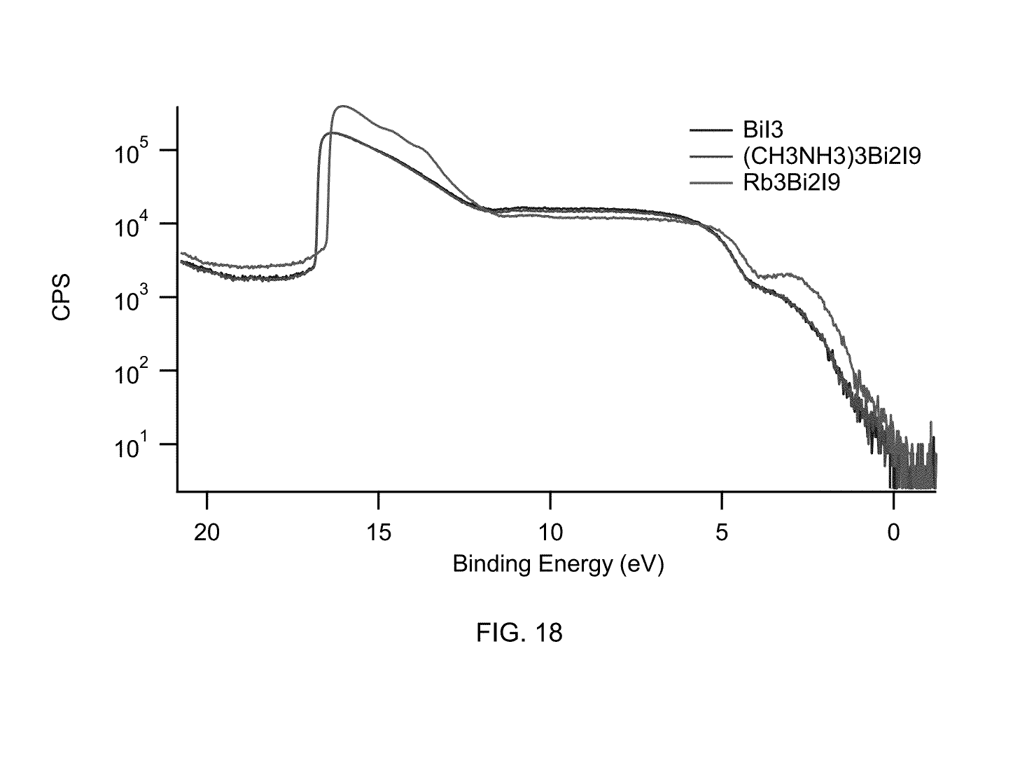

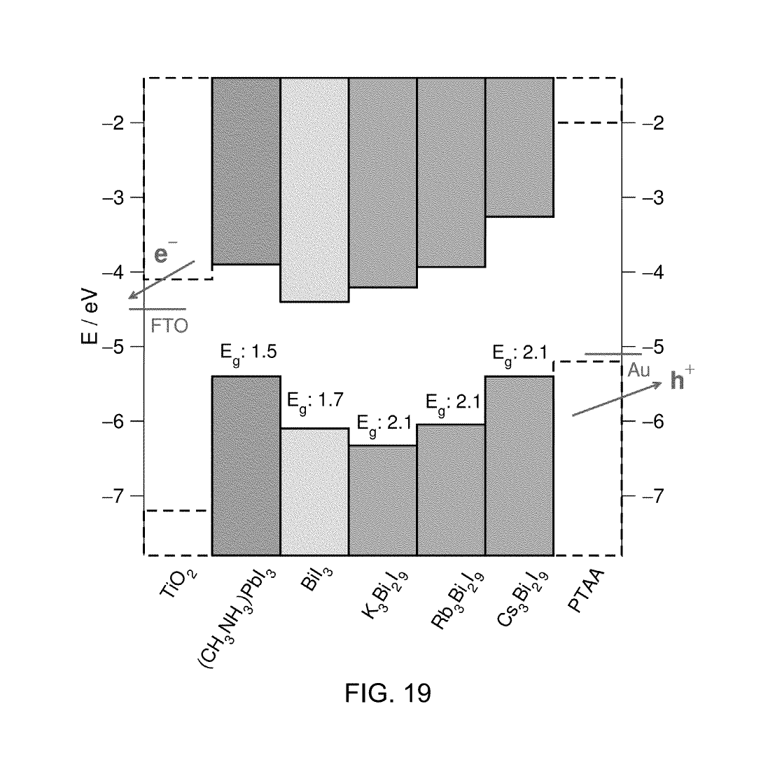

From the UPS spectra (FIGS. 17 and 18), the valence band maximum of the materials, was estimated as being equal to the distance between the high and low energy sharp edges of the UPS signal, minus the incident photon energy, 21.22 eV. From the valence band maximum and the optical band gap, the conduction band minimum was determined. These values are displayed in FIG. 19, along with literature values for the lead perovskite and electrodes. It can be noted that the efficient electron extraction from K₃Bi₂I₉ (1) and Rb₃Bi₂I₉ (2) may be expected due to their low-lying conduction band minimum. On the other hand, efficient hole extraction from Cs₃Bi₂I₉ (3) may be expected due to its high-lying valence band maxima.

### Initial Solar Cell Testing Results

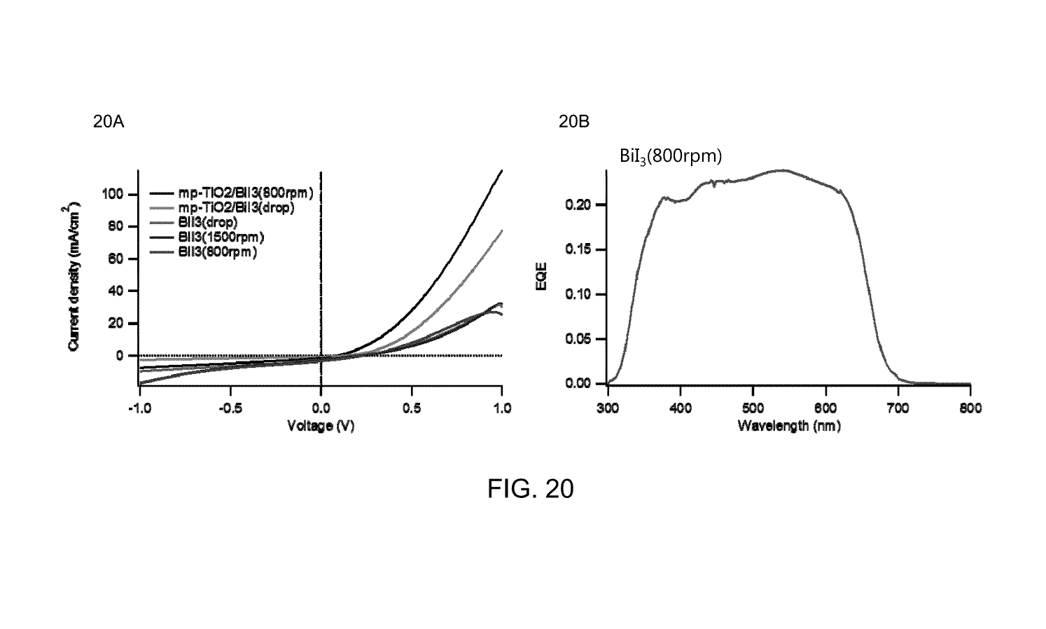

Solar cells were fabricated on a glass/FTO substrate with a dense TiO₂ hole blocking layer, a mesoporous TiO₂ layer on some samples, then the active layer either spin-coated or drop-cast from a DMF, THF, CH₃CN, DMSO or mixed solvent solution, then the hole transporting/electron blocking layer composed of PTAA doped with Li-TFSI, and finally an evaporated Au electrode. Preliminary BiI₃ solar cells gave promising results, with a maximum PCE of 0.23% and a reasonably broad EQE over 20% between 400-650 nm (FIG. 20).

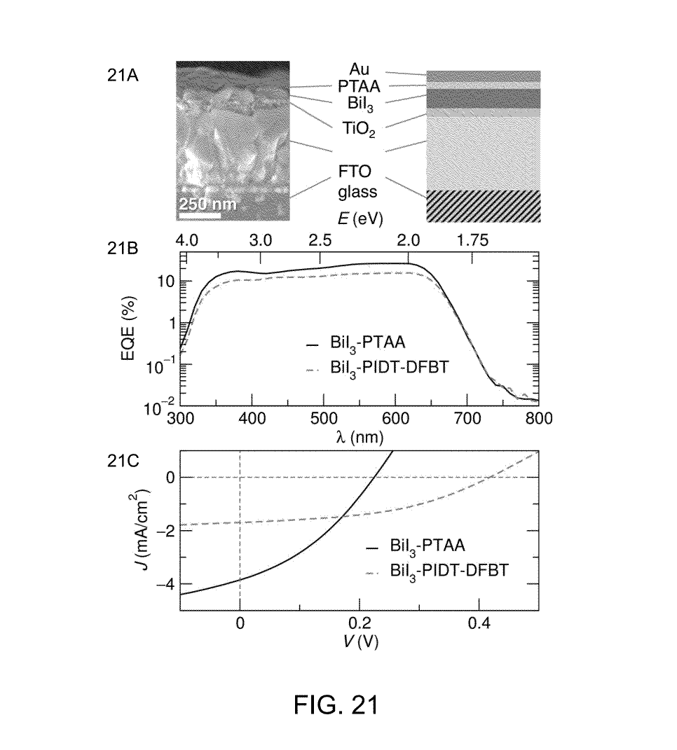

Solar cells with BiI₃ absorber layers were further fabricated in a planar heterojunction structure (FIG. 21A). Thin films were deposited onto fluorine-doped tin oxide (FTO) on glass under ambient conditions resulting in the final device structure glass/FTO/d-TiO₂/BiI₃/HTL/Au, with the HTL being either the PTAA or the PIDT-DFBT[43], and approximately 100 nm thick BiI₃ layers. Upon illumination, charge carriers can be generated within the BiI₃ layer and at the hetero-interface with the ETL TiO₂. The photo-generated electrons are extracted through the TiO₂ layer, and the holes are extracted through the organic layer. The heterojunction solar cells studied here display sub-1% efficiency, but demonstrate that bismuth halides can be used as the active layer in solution-processed solar cells. Representative external quantum efficiency (EQE) spectra and current density-voltage (JV) characteristics of the solar cell devices are presented in FIGS. 21B and 21C, and device parameters are summarized in Table 4. The EQE spectra of the devices cover the visible spectrum with a sharp absorption onset around 700 nm, which is in good agreement with the BiI₃ optical band gap close to 1.8 eV. It is interesting to note that the low-energy Urbach tail of the EQE of BiI₃ is steep and does not show much structure, potentially suggesting little disorder-induced broadening. The open circuit voltage (Voc) was low as was expected due to the alignment of the transport levels of BiI₃ with the ETL and the HTL (FIG. 19). When the deeper VBM polymer PIDT-DFBT is used as the HTL instead of PTAA in the BiI₃ devices, both Voc and fill factor (FF) were improved although a decrease in the Jsc was observed. The relatively good quantum efficiency (20% in the PTAA devices) suggests that absorption across the spectrum and charge generation is relatively efficient, and therefore improvement of the contacts is likely the best strategy for increasing the PCE of BiI₃ devices.

### Tables

TABLE 1
Crystallographic parameters, number of formula units per unit cell Z,
unit cell dimensions a, b, c (Å), and β (°) and volume per formula
unit V_{FU} (Å³), determined from single crystal X-ray experiments
at room temperature for A₃Bi₂I₉ (A = K (1), Rb (2), Cs (3),
CH₃NH₃ (4), (NH₂(CH)NH₂) (5)), and (NH₃(CH)₂NH₃)₂Bi₂I₁₀ (6).

| Compound | Space group | Z | a | b | c | β | V_{FU} | comments |
|---|---|---|---|---|---|---|---|---|
| 1 | P2₁/c | 4 | 14.48 | 8.00 | 24.93 | 123.4 | 603.08 | |
| 2 | P2₁/c | 4 | 14.62 | 8.19 | 25.47 | 124.7 | 626.75 | |
| 3 | P6₃/mmc | 2 | 8.47 | | 21.17 | | 647.89 | |
| 4 | | 2 | 8.58 | | 21.75 | | 693.28 | a |
| 5 | | 2 | 8.67 | | 21.79 | | 709.59 | a |
| 6 | P2₁/c | 2 | 8.44 | 13.86 | 13.66 | 110.130 | 750.00 | |
| 7 | P 2₁/n | 4 | 22.616 | 8.494 | 29.763 | 98.56 | 5653.48 | |

a Approximate structure with unresolved disorder of counter cations

TABLE 2
Crystallographic parameters of Py₃Bi₂I₉

| Empirical formula | Py₃Bi₂I₉ |
|---|---|
| Cyrstal habit, color | rectangle |
| Cyrstal descript | Red |
| Crystal system | Monoclinic |
| Space group | P 2₁/n |
| Volume | 5653.48 |
| a | 22.616 |
| b | 8.494 |
| c | 29.763 |
| Alpha | 90 |
| Beta | 98.56 |
| Gamma | 90 |
| Z | 4 |
| Fo weight | 2304.93 |
| Density (g/cm³) | 2.6019 |
| Abs coeff (mm⁻¹) | 11.166 |
| F₀₀₀ | 4144 |
| Total no reflections | 14230 |
| Unique reflections | 7850 |
| Rᵢₙₜ | 0.10 |
| Final R indices (R1, wr2) | .0985, .1724 |
| Largest diff peak & hole e⁻A⁻³ | 6.165 and −3.363 |
| GOF | 1.110 |

TABLE 3
Device parameters of BiI₃ solar cells with
PTAA as electron blocking layer.

| Layer | V_{oc} [V] | J_{sc} [mA/cm²] | FF | PCE [%] |
|---|---|---|---|---|
| mp-TiO₂/BiI₃ (800 rpm) | 0.08 | 1.38 | 0.29 | 0.03 |
| mp-TiO₂/BiI₃ (drop) | 0.12 | 0.65 | 0.31 | 0.03 |
| BiI₃ (drop) | 0.20 | 2.46 | 0.26 | 0.13 |
| BiI₃ (1500 rpm) | 0.21 | 2.81 | 0.25 | 0.15 |
| BiI₃ (800 rpm) | 0.23 | 3.43 | 0.29 | 0.23 |

TABLE 4
Photovoltaic properties of BiI₃ devices with various electron
blocking layer: open circuit voltage V_{oc}, short circuit current
J_{sc} (from JV or EQE measurements, respectively), fill
factor FF, and power conversion efficiency PCE.

| | J_{sc} [mA/cm²] | | | | |
|---|---|---|---|---|---|
| Device | V_{oc} [V] | From JV | From EQE | FF | PCE [%] |
| BiI₃-PTAA | 0.22 | 3.85 | 3.79 | 0.35 | 0.30 |
| BiI_PIDT-DFBT | 0.42 | 1.70 | 2.39 | 0.45 | 0.32 |

The complex bismuth iodides 2-4 showed a photovoltaic effect too in the initial device test but lower power conversion efficiencies.

The results on the analysis of film morphology and material energy levels, suggest that the low performance could very well be not a result of an intrinsic limitation of the materials but rather device structure and process related. PV efficiency could be dramatically improved by the following operations:
Achieve more uniform active layer, electron blocking layer and hole blocking layer to reduce leaking current, by using different solvent, concentration, coating methods, drying temperature, surface treatment etc.
Reduce active layer impurity and degradation, optimize film thickness and interface contacts to improve charge separation and transportation.
Adopt new electron and hole blocking layers with more suitable work functions matching the energy levels of the bismuth halides, such as a hole transporting/electron blocking layer with a deeper HOMO will lead to higher device V_{oc}.

TABLE 5
Initial device parameters of Rb₃Bi₂I₉ solar cells.

| Layer | V_{oc} [V] | J_{sc} [mA/cm²] | FF | PCE [%] |
|---|---|---|---|---|
| Rb₃Bi₂I₉ (800 rpm) | 0.0112 | 0.1264 | 0.0944 | 0.0001 |
| Rb₃Bi₂I₉ (drop) | 0.0655 | 0.2139 | 0.2518 | 0.0035 |

TABLE 6
Initial device parameters of (CH₃NH₃)₃Bi₂I₉ solar cells.

| Layer | V_{oc} [V] | J_{sc} [mA/cm²] | FF | PCE [%] |
|---|---|---|---|---|
| (CH₃NH₃)₃Bi₂I₉ (800 rpm) | 0.0705 | 0.0802 | 0.2513 | 0.0014 |

TABLE 7
Device parameters of various bismuth halide complexes fabricated
using various solvents, annealing temperatures, film thicknesses,
and either PTAA or spiro-MeOTAD as hole transporting/electron
blocking layer.

| Layer | V_{oc} [V] | J_{sc} [mA/cm²] | FF | PCE [%] |
|---|---|---|---|---|
| Rb₃Bi₂I₉ | 0.26 | 0.29 | 0.35 | 0.027 |
| (CH₃NH₃)₃Bi₂I₉ | 0.29 | 0.24 | 0.30 | 0.021 |
| (HDA)₂Bi₂I₁₀ | 0.39 | 0.011 | 0.27 | 0.0011 |
| Py₃Bi₂I₉ | 0.34 | 0.033 | 0.32 | 0.0035 |
| Cs₃Bi₂I₉ | 0.22 | 0.38 | 0.35 | 0.029 |

Several bismuth and antimony halides compounds were reported for (potentially) solar cell applications, including the publications from the inventors [44,45]. The closely related cesium antimony iodide Cs₃Sb₂I₉ was investigated as solar cell absorber layer, and the electronic structure of its polymorphs has been calculated by DFT [46]. Structure analysis was conducted on Cs₃Bi₂I₉, MA₃Bi₂I₉ and MA₃Bi₂I₉Clₓ and investigated as solar cell absorber layer, with device power conversion efficiency as high as 1% reported [47,48]. These work provide evidence for the potential of these materials in solar cell application.

### REFERENCES

[1] Reinhard, P., Chiril, A., Bl, P., Pianezzi, F., Nishiwaki, S., Buecheler, S., Tiwari, A. N. (2013). Review of Progress Toward 20% Efficiency Flexible CIGS Solar Cells and Manufacturing Issues of Solar Modules. IEEE J Photovolt., 3(1), 572-580.
[2] Parida, B., Iniyan, S., & Goic, R. (2011). A review of solar photovoltaic technologies. Renew. Sust. Energ. Rev., 15(3), 1625-1636. doi:10.1016/j.rser.2010.11.032
[3] Green, M. A., Emery, K., Hishikawa, Y., Warta, W., & Dunlop, E. D. (2014). Solar cell efficiency tables (version 44). Prog. Photovolt. Res. Appl., 22(7), 701-710. doi:10.1002/pip.2525
[4] Kamat, P. V. (2013). Quantum Dot Solar Cells. The Next Big Thing in Photovoltaics. J. Phys. Chem. Lett., 4(6), 908-918. doi:10.1021/jz400052e
[5] Delbos, S. (2012). Kesterite thin films for photovoltaics: a review. EPJ Photovoltaics, 3, 35004-1-35004-13. doi:10.1051/epjpv/2012008
[6] Green, M. a., Ho-Baillie, A., Snaith, H. J. (2014). The emergence of perovskite solar cells. Nature Photon., 8(7), 506-514. doi:10.1038/nphoton.2014.134
[7] A. Kojima, K. Teshima, Y. Shirai, T. Miyasaka (2009). Organometal halide perovskites as visible light sensitizers for photovoltaic cells. J. Am. Chem. Soc., 131(17), 6050-6051. doi:10.1021/ja809598r
[8] Zhou, H., Chen, Q., Li, G., Luo, S., Song, T.-B., Duan, H.-S., Hong, Z., You, J., Liu, Y., Yang, Y. (2014). Interface engineering of highly efficient perovskite solar cells. Science, 345(6196), 542-546. doi:10.1126/science.1254050
[9] a) F. Hao, C. C. Stoumpos, R. P. H. Chang, M. G. Kanatzidis (2014). Anomalous band gap behavior in mixed Sn and Pb perovskites enables broadening of absorption spectrum in solar cells. J. Am. Chem. Soc. doi:10.1021/ja5033259; b) M. H. Kumar, S. Dharani, W. L. Leong, P. P. Boix, R. R Prabhakar, T. Baikie, C. Shi, H. Ding, R. Ramesh, M. Asta, M. Graetzel, S. G. Mhaisalkar, N. Mathews (2014). Lead-Free Halide Perovskite Solar Cells with High Photocurrents Realized Through Vacancy Modulation. Adv. Mater., doi:10.1002/adma.201401991; c) N. K. Noel, S. D. Stranks, A. Abate, Wehrenfennig, C., Guarnera, S., Haghighirad, A., Sadhanala, A., Eperon, G. E, Pathak, S. K., Johnston, M. B, Petrozza, A., Herz, L., Snaith, H. (2014). Lead-Free Organic-Inorganic Tin Halide Perovskites for Photovoltaic Applications. Energ. Environ. Sci., 7, 3061-3068. doi:10.1039/c4ee01076k.
[10] L.-M. Wu, X.-T. Wu, L. Chen, L. (2009). Structural overview and structure-property relationships of iodoplumbate and iodobismuthate. Coordination Chemistry Reviews, 253(23-24), 2787-2804. doi:10.1016/j.ccr.2009.08.003
[11] Boopathi, K. M., Raman, S., Mohanraman, R., Chou, F.-C., Chen, Y.-Y., Lee, C.-H., Chang, F.-C. Chu, C.-W. (2014). Solution-processable bismuth iodide nanosheets as hole transport layers for organic solar cells. Solar Energy Materials and Solar Cells, 121, 35-41. doi:10.1016/j.solmat.2013.10.031
[12] Colella, S., Mosconi, E., Fedeli, P., Listorti, A., Gazza, F., Orlandi, F., Ferro, P., Besagni, T, Rizzo, A., Calestani, G., Gigli, G., De Angelis, F., Mosca, R. (2013). MAPbI 3-x Cl x Mixed Halide Perovskite for Hybrid Solar Cells: The Role of Chloride as Dopant on the Transport and Structural Properties. Chemistry of Materials, 25(22), 4613-4618. doi:10.1021/cm402919x
[13] Fourcroy, P. H., Carré, D., Thévet, F., & Rivet, J. (1991). Structure du tétraiodure de cuivre(I) et de bismuth(III), CuBiI4. Acta Crystallographica Section C Crystal Structure Communications, 47(10), 2023-2025. doi:10.1107/50108270191005309
[14] a) Stoumpos, C. C., Malliakas, C. D., & Kanatzidis, M. G. (2013). Semiconducting tin and lead iodide perovskites with organic cations: phase transitions, high mobilities, and near-infrared photoluminescent properties. Inorg. Chem., 52(15), 9019-38. doi:10.1021/ic401215x. b) Koh, T. M., Fu, K., Fang, Y., Chen, S., Sum, T. C., Mathews, N., Mhaisalkar, S. G., Boix, P. P., Baikie, T. (2013). Formamidinium-Containing Metal-Halide: An Alternative Material for Near-IR Absorption Perovskite Solar Cells. J. Phys. Chem. C, (8), 140117105541008. doi:10.1021/jp411112k. c) Eperon, G. E., Stranks, S. D., Menelaou, C., Johnston, M. B., Herz, L. M., Snaith, H. J. (2014). Formamidinium lead trihalide: a broadly tunable perovskite for efficient planar heterojunction solar cells. Energy & Environmental Science, 7(3), 982-988. doi:10.1039/c3ee43822h
[15] a) Lindquist, O. (1968). The Crystal Structure of Caesium Bismuth Iodide, Cs₃Bi₂I₉. Acta Chem. Scandinavica, 22, 2943-2952. b) Arakcheeva, A., Chapuis, G., Meyer, M. (2001). The LT phase of Cs₃Bi₂I₉. Z. Kristallogr. 216, 199-205.
[16] a) C. Preitschaft, Dissertation: Ternäre und quaternare Materialien mit komplexen Thio-, Selenido- und Halogenid-Anionen, Regensburg (2004). b) Sidey, V. I., Voroshilov, Y. V., Kun, S. V., & Peresh, E. Y. (2000). Crystal growth and X-ray structure determination of Rb₃Bi₂I₉. J. Alloys Comp., 296(1-2), 53-58. doi:10.1016/S0925-8388(99)00481-8.
[17] Qiu, J., Qiu, Y., Yan, K., Zhong, M., Mu, C., Yan, H., Yang, S. (2013). All-solid-state hybrid solar cells based on a new organometal halide perovskite sensitizer and one-dimensional TiO₂ nanowire arrays. Nanoscale, 5(8), 3245-8. doi:10.1039/c3nr00218g
[18] Roldán-Carmona, C., Malinkiewicz, O., Soriano, A., Minguez Espallargas, G., Garcia, A., Reinecke, P., Kroyer, T. Dar, M. I., Nazeeruddin, M. K., Bolink, H. J. (2014). Flexible high efficiency perovskite solar cells. Energy & Environmental Science, 7(3), 994-997. doi:10.1039/c3ee43619e
[19] Zhao, Y., Nardes, A. M., Zhu, K. (2014). Effective hole extraction using MoOₓ—Al contact in perovskite CH₃NH₃PbI₃ solar cells. Applied Physics Letters, 104(21), 213906-1-213906-4. doi:10.1063/1.4880899
[20] G. M. Sheldrick, SHELXS-97, (1997) Program for the solution of crystal structures, Universität Göttingen, Germany.
[21] G. M. Sheldrick, SHELXL-97, (1997) Program for the Refinement of Crystal Structures, Universität Göttingen, Germany.
[22] Momma, K.; Izumi, F. (2011) VESTA3 for Three-Dimensional Visualization of Crystal, Volumetric and Morphology Data. J. Appl. Crystallogr., 44, 1272-1276.
[23] Kresse, G.; Hafner, J. (1993) Ab initio molecular dynamics for liquid metals. Phys. Rev. B, 47, 558-561.
[24] Kresse, G.; Hafner, J. (1994) Ab initio molecular-dynamics simulation of the liquid-metal-amorphous-semiconductor transition in germanium. Phys. Rev. B, 49, 14251-14269.
[25] Kresse, G.; Furthmüller, J. (1996) Efficiency of ab-initio total energy calculations for metals and semiconductors using a plane-wave basis set. Comput. Mat. Sci.
[26] Kresse, G.; Furthmüller, J. (1996) Efficient iterative schemes for ab initio total-energy calculations using a plane-wave basis set. Phys. Rev. B, 54, 11169-11186.
[27] Perdew, J. P.; Burke, K.; Ernzerhof, M. (1996) Generalized gradient approximation made simple. Phys. Rev. Lett. 77, 3865-3868.
[28] Guo-Qing, L., Gang, X., Zheng, F., Guo-Cong, G. (2008). Syntheses and Characterizations of (CH₃CH₂CH₂CH₂NH₃)₆(Bi₂I₆)(I)₂I₃ and (NH₃CH₂CH₂NH₃)₂Bi₂I₁₀. Chinese J. Struct. Chem., 27(10), 1275-1280. Retrieved from http://d.wanfangdata.com.cn/periodical_jghx200810021.aspx.
[29] Miniewicz, A., Jakubas, R. (1990). On the nature of the low tempeature phase transition in (CH₃NH₃)₃Bi₂I₉ studied by the pyroelectric method. Ferroelectrics, 110, 261-269.
[30] Kim, H.-S., Lee, C.-R., Im, J.-H., Lee, K.-B., Moehl, T., Marchioro, A., Moon, S.-J., Humphry-Baker, R., Yum, J.-H., Moser, J. E., Grätzel, M., Park, N.-G. (2012). Lead iodide perovskite sensitized all-solid-state submicron thin film mesoscopic solar cell with efficiency exceeding 9%. Scientific Reports, 2, 1-7. doi:10.1038/srep00591.
[31] EP1122291A2, filed Jan. 11, 2001, International Business Machines Corporation, David Brian Mitzi, Layered organic-inorganic perovskites having metal-deficient inorganic frameworks.
[32] U.S. Pat. No. 8,574,953 B2, filed Jan. 31, 2012, International Business Machines Corporation, Patrick W. DeHaven, David R. Medeiros, David B. Mitzi, Low temperature melt-processing of organic-inorganic hybrid.
[33] WO2013126385 A1, filed Feb. 20, 2013, Northwestern University, Mercouri G. Kanatzidis, In Chung, Konstantinos Stoumpos, Photoluminescent compounds.
[34] I. Chung, B. Lee, J. He, R. P. H. Chang. M. G. Kanatzidis. All-solid-state dye-sensitized solar cells with high efficiency, Nature, 2012, 485, 486-490.
[35] M. M. Lee, J. Teuscher, T. Miyasaka, T. N. Murakami, H. J. Snaith. Efficient hybrid solar cells based on meso-superstructured organometal halide perovskites, Science, 2012, 338, 643-647. DOI: 10.1126/science.1228604.
[36] H. J. Snaith, M. M. Lee, T. Murakami. Optoelectronic devices with organometal perovskites with mixed anions, W02013/171517A1.
[37] C. Feldmann, A. Luz, WO2010099858.
[38] B. O'Regan, M. Grätzel. Nature 1990, 353, 737-740.
[39] H. Snaith and L. Schmidt-Mende, Adv. Mater., 2007, 19, 3187-3200.
[40] J. H. Heo, S. H. Im, J. H. Noh, T. N. Mandal, C.-S. Lim, J. A. Chang, Y. H. Lee, H.-J. Kim, A. Sarkar, M. K. Nazeeruddin, M. Gratzel and S. I. Seok. Nature Photonics, 2013, 7, 486-491.
[41] Oldag, T., Aussieker, T., Keller, H.-L., Preitschaft, C., & Pfitzner, A. (2005). Solvothermale Syntheseund Bestimmung der Kristallstrukturen von AgBiI4 and Ag3BiI6. Z. Anorg. Allg. Chem., 631, 677-682. doi:10.1002/zaac.200400508.
[42] Fourcroy, P. H., Carré, D., Thévet, F., & Rivet, J. (1991). Structure du tétraiodure de cuivre(I) et de bismuth(III), CuBiT4. Acta Crystallogr. Section C, C47, 2023-2025. doi:10.1107/S0108270191005309.
[43] Y. Zhang, S.-C. Chien, K.-S. Chen, H.-L. Yip, Y. Sun, J. A. Davies, F.-C. Chen, and A. K.-Y. Jen, Chem. Commun. 47, 11026 (2011).
[44] Anna J. Lehner, Hengbin Wang, Douglas H. Fabini, Christopher D. Liman, Claire-Alice Hébert, Erin E. Perry, Ming Wang, Guillermo C. Bazan, Michael L. Chabinyc, and Ram Seshadri. Electronic structure and photovoltaic application of BiI₃. Applied Physics Letters, 107, 131109 (2015).
[45] Anna J. Lehner, Douglas H. Fabini, Hayden A. Evans, Claire-Alice Hébert, Sara R. Smock, Jerry Hu, Hengbin Wang, Josef W. Zwanziger, Michael L. Chabinyc, and Ram Seshadri. Crystal and Electronic Structures of Complex Bismuth Iodides A₃Bi₂T₉ (A=K, Rb, Cs) Related to Perovskite: Aiding the Rational Design of Photovoltaics. Chem. Mater. 2015, 27, 7137-7148.
[46] Saparov, B.; Hong, F.; Sun, J.-P.; Duan, H.-S.; Meng, W.; Cameron, S.; Hill, I. G.; Yan, Y.; Mitzi, D. B. Thin-Film Preparation and Characterization of Cs3Sb2I9: A Lead-Free Layered Perovskite Semiconductor. Chem. Mater. 2015, 27, 5622-5632.
[47] Byung-Wook Park, Bertrand Philippe, Xiaoliang Zhang, Hakan Rensmo, Gerrit Boschloo, Erik M. J. Johansson. Bismuth Based Hybrid Perovskites A₃Bi₂T₉ (A: Methylammonium or Cesium) for Solar Cell Application. Adv. Mater. 2015, DOI: 10.1002/adma.201501978.
[48] Shijing Sun, Satoshi Tominaka, Jung-Hoon Lee, Fei Xie, Paul D. Bristowe, Anthony K. Cheetham. Synthesis, Crystal Structure and Properties of a Perovskite-Related Bismuth Phase, (NH₄)₃Bi₂I₉. arXiv:1509.08126, 2015.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching.

1. An optoelectronic solid state thin film device comprising:
a semiconductor active layer deposited between a first electrode and a second electrode, wherein the active layer comprises a material of the formula AₐB_{b}MₘXₓ, wherein:
A represents a monovalent inorganic cation, a monovalent organic cation, or mixture of different monovalent organic or inorganic cations;
B represents a divalent inorganic cation, a divalent organic cation, or mixture of different divalent organic or inorganic cations;
M represents Bi³⁺ or Sb³⁺;
X represents a monovalent halide anion, or mixture of different monovalent halide anions; and
a, b represent 0 or any positive numbers, m, x represent any positive numbers, and a+2b+3m=x.

2. The device of claim 1, further comprising:
a substrate, wherein the first electrode is deposited on the substrate;
an electron conducting layer deposited between the active layer and one of the first or second electrode; and
a hole conducting layer deposited between the active layer and the other of the first or second electrode.

3. The device of claim 1, wherein the device is a solar cell device.

4. The device of claim 1, wherein A is selected from the group consisting of H⁺, H₃O⁺, NH₄⁺, H₃NOH⁺, Li⁺, Na⁺, K⁺, Rb⁺, Cs⁺, Cu⁺, Ag⁺, BiO⁺, methylammonium CH₃NH₃⁺, ethylammonium (C₂H₅)NH₃⁺, alkylammonium, formamidinium NH₂(CH)NH₂⁺, guanidinium C(NH₂)₃⁺, imidazolium C₃N₂H₅⁺, hydrazinium H₂N—NH₃⁺ azetidinium (CH₂)₃NH₂⁺, dimethylammonium (CH₃)₂NH₂⁺, tetramethylammonium (CH₃)₄N⁺, phenylammonium C₆H₅NH₃⁺, arylammonium, and heteroarylammonium.

5. The device of claim 1, wherein B is a divalent primary, secondary, tertiary, or quaternary organic ammonium cation with 1 to 100 carbons and 2 to 30 heteroatoms, wherein two of the heteroatoms are positively charged nitrogen atoms.

6. The device of claim 1, wherein B is selected from the group consisting of Mg²⁺, Ca²⁺, Sr²⁺, Ba²⁺, Ti²⁺, V²⁺, Ni²⁺, Cr²⁺, Co²⁺, Fe²⁺, Sn²⁺, Cu²⁺, Ag²⁺, Zn²⁺, Mn²⁺, NH₃CH₂CH₂NH₃²⁺, NH₃(CH₂)₆NH₃²⁺, NH₃(CH₂)₈NH₃²⁺ and NH₃C₆H₄NH₃²⁺.

7. The device of claim 1, wherein the active layer comprises a material selected from the group consisting of MX₃, AMX₄, A₃MX₆,A₃M₂X₉ perovskites, A₂A′MX₆ double perovskites, and Aₙ₊₁A′_{n/2}M_{n/2}X₃ₙ₊₁ Ruddlesden-Popper phases.

8. The device of claim 1, wherein the active layer is a bismuth halide selected from the group consisting of K₃Bi₂I₉, Rb₃Bi₂I₉, Cs₃Bi₂I₉, (CH₃NH₃)₃Bi₂I₉, (NH₂(CH)NH₂)₃Bi₂I₉, and (NH₃(CH₂)₂NH₃)₂Bi₂I₁₀.

9. The device of claim 1, wherein the active layer contains a [MX₆] octahedra connected via shared apexes, edges or faces.

10. The device of claim 2, further comprising a mesoporous TiO₂ layer between the electron conducting layer and the active layer.

11. The device of claim 2, wherein the electron conducting layer is selected from the group consisting of TiO₂, ZnO, ZrO₂, Al₂O₃, BaSnO₃, InGaO₃, and SrGeO₃.

12. The device of claim 2, wherein the hole conducting layer is selected from the group consisting of poly(3,4-ethylenedioxythiophene): polystyrene sulfonate (PEDOT:PSS), poly(3-hexylthiophene-2,5-diyl) (P3HT), biscarbazolylbenzene, VOₓ, NbOₓ, MoOₓ, WOₓ, NiOₓ, where x is less than 3, and a compound as follows:

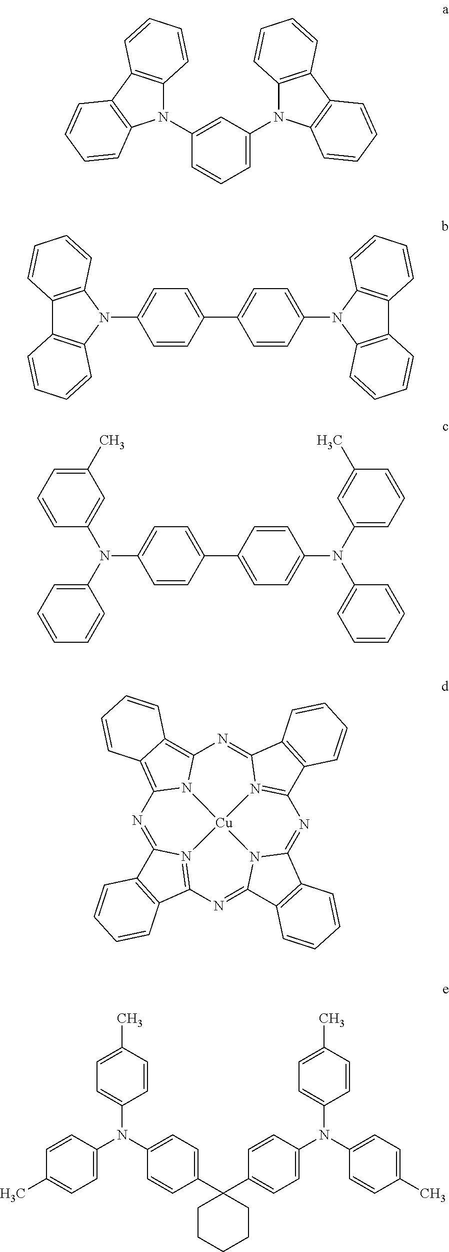

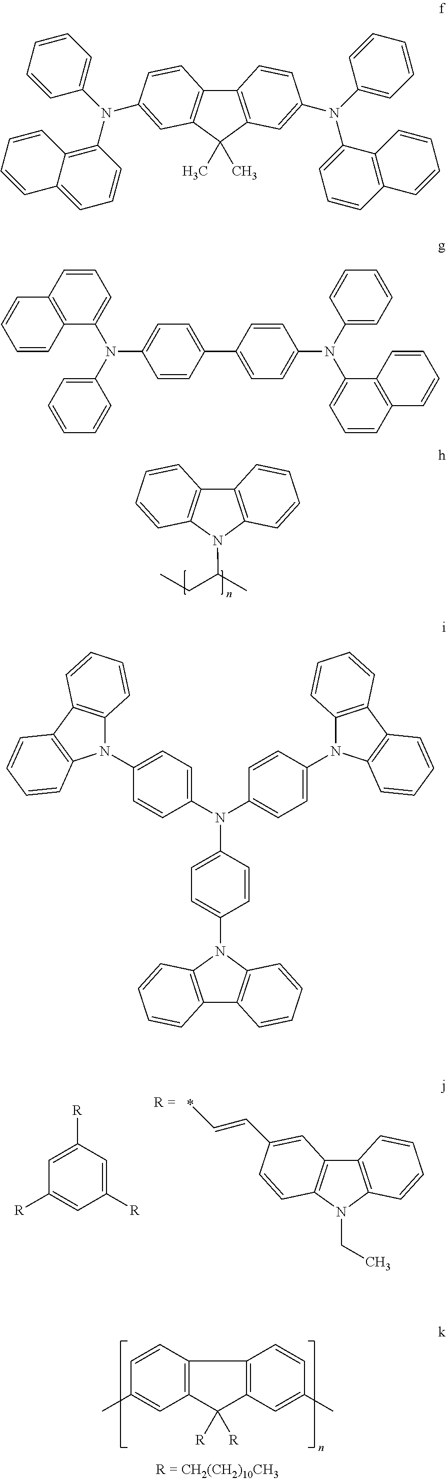

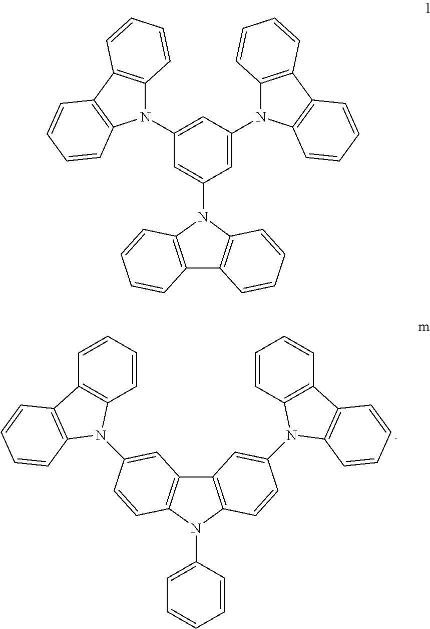 [SMILES: c1ccc2c(c1)c1ccccc1n2-c1cc(-n2c3ccccc3c3ccccc32)cc(-n2c3ccccc3c3ccccc32)c1 ; c1ccc(-n2c3ccc(-n4c5ccccc5c5ccccc54)cc3c3cc(-n4c5ccccc5c5ccccc54)ccc32)cc1]

13. The device of claim 1, wherein the active layer is selected to have a bandgap no more than 2.1 eV.

14. A method of forming a solid state thin film optoelectronic device, the method comprising:
depositing an active layer between a first electrode and a second electrode, wherein the active layer comprises a semiconducting material of the formula AₐB_{b}MₘXₓ, wherein:
A represents a monovalent inorganic cation, a monovalent organic cation, or mixture of different monovalent organic or inorganic cations;
B represents a divalent inorganic cation, a divalent organic cation, or mixture of different divalent organic or inorganic cations;
M represents Bi³⁺ or Sb³⁺;
X represents a monovalent halide anion, or mixture of different monovalent halide anions; and
a, b represent 0 or any positive numbers, m, x represent any positive numbers, and a+2b+3m=x.

15. The method of claim 14, further comprising:
depositing the first electrode onto a substrate;
depositing an electron conducting layer between the active layer and one of the first or second electrode; and
depositing a hole conducting layer between the active layer and the other of the first or second electrode.

16. The method of claim 14, wherein A is selected from the group consisting of H⁺, H₃O⁺, NH₄⁺, H₃NOH⁺, Li⁺, Na⁺, K⁺, Rb⁺, Cs⁺, Cu⁺, Ag⁺, BiO⁺, methylammonium CH₃NH₃⁺, ethylammonium (C₂H₅)NH₃⁺, alkylammonium, formamidinium NH₂(CH)NH₂⁺, guanidinium C(NH₂)₃⁺, imidazolium C₃N₂H₅⁺, hydrazinium H₂N—NH₃⁺ azetidinium (CH₂)₃NH₂⁺, dimethylammonium (CH₃)₂NH₂⁺, tetramethylammonium (CH₃)₄N⁺, phenylammonium C₆H₅NH₃⁺, arylammonium, and heteroarylammonium.

17. The method of claim 14, wherein B is a divalent primary, secondary, tertiary, or quaternary organic ammonium cation with 1 to 100 carbons and 2 to 30 heteroatoms, wherein two of the heteroatoms are positively charged nitrogen atoms.

18. The method of claim 14, wherein B is selected from the group consisting of Mg²⁺, Ca²⁺, Sr²⁺, Ba²⁺, Ti²⁺, V²⁺, Ni²⁺, Cr²⁺, Co²⁺, Fe²⁺, Sn²⁺, Cu²⁺, Ag²⁺, Zn²⁺, Mn²⁺, NH₃CH₂CH₂NH₃²⁺, NH₃(CH₂)₆NH₃²⁺, NH₃(CH₂)₈NH₃²⁺ and NH₃C₆H₄NH₃²⁺.

19. The method of claim 14, wherein the active layer comprises a material selected from the group consisting of MX₃, AMX₄, A₃MX₆,A₃M₂X₉ perovskites, A₂A′MX₆ double perovskites, and Aₙ₊₁A′_{n/2}M_{n/2}X₃ₙ₊₁ Ruddlesden-Popper phases.

20. The method of claim 14, wherein the active layer is a bismuth halide selected from the group consisting of K₃Bi₂I₉, Rb₃Bi₂I₉, Cs₃Bi₂I₉, (CH₃NH₃)₃Bi₂I₉, (NH₂(CH)NH₂)₃Bi₂I₉, and (NH₃(CH₂)₂NH₃)₂Bi₂I₁₀.

21. The method of claim 14, wherein the active layer contains a [MX₆] octahedra connected via shared apexes, edges or faces.

22. The method of claim 15, further comprising depositing a mesoporous TiO₂ layer between the electron conducting layer and the active layer.

23. The method of claim 15, wherein the electron conducting layer is selected from the group consisting of TiO₂, ZnO, ZrO₂, Al₂O₃, BaSnO₃, InGaO₃, and SrGeO₃.

24. The method of claim 15, wherein the hole conducting layer is selected from the group consisting of poly(3,4-ethylenedioxythiophene): polystyrene sulfonate (PEDOT:PSS), poly(3-hexylthiophene-2,5-diyl) (P3HT), biscarbazolylbenzene, VOₓ, NbOₓ, MoOₓ, WOₓ, NiOₓ, where x is less than 3, and a compound as follows:

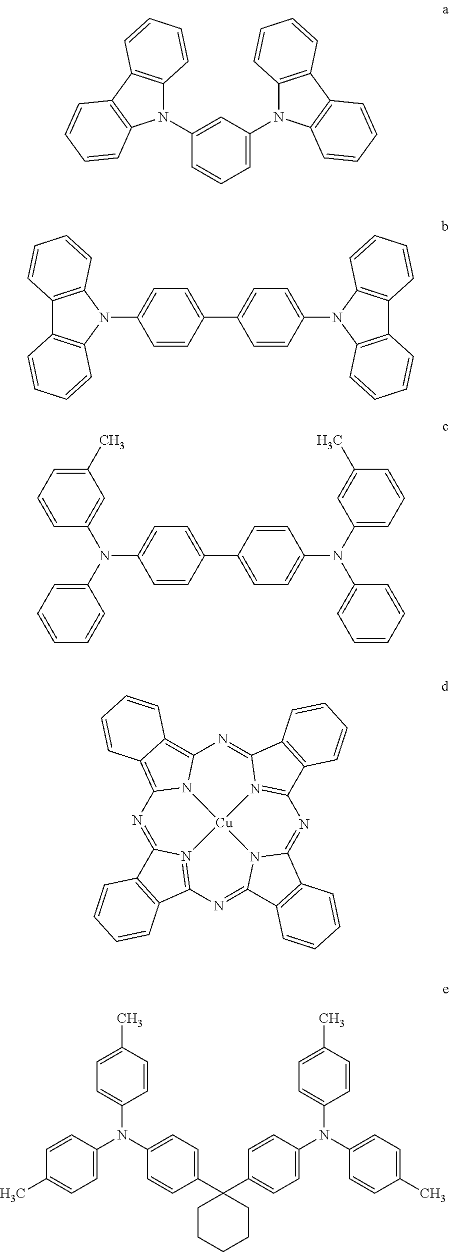

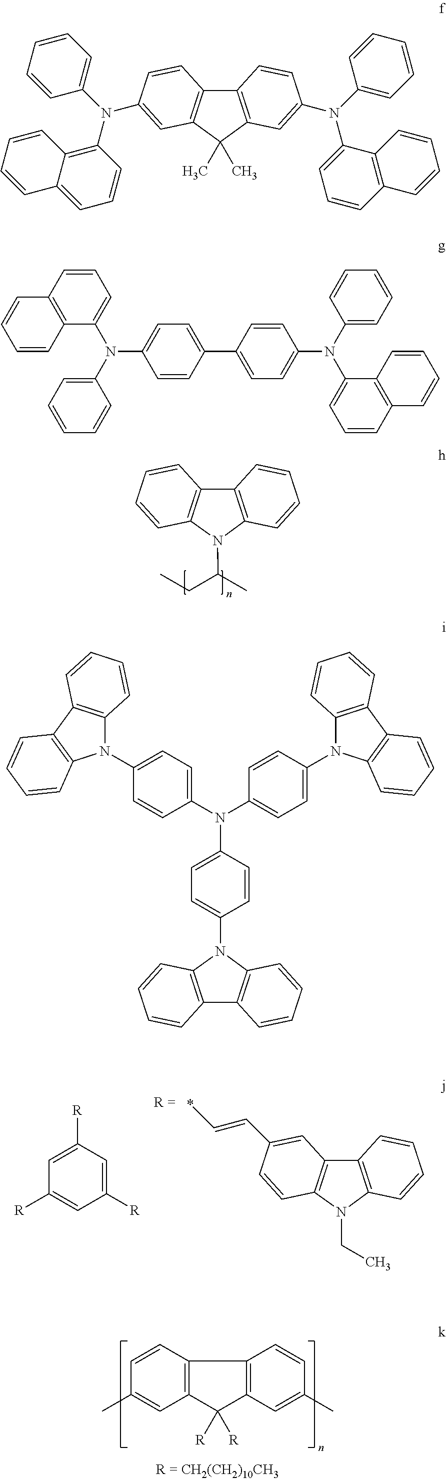

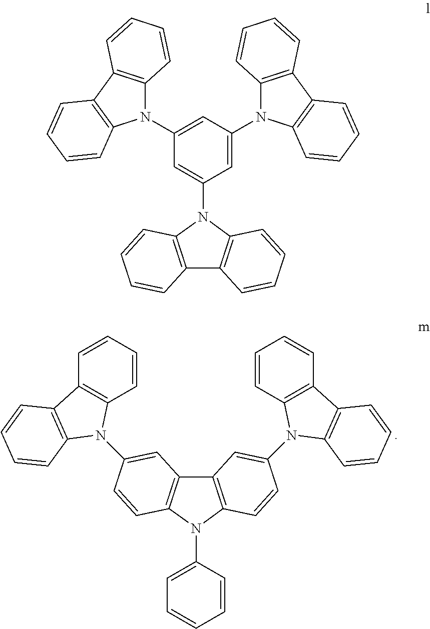 [SMILES: c1ccc2c(c1)c1ccccc1n2-c1cc(-n2c3ccccc3c3ccccc32)cc(-n2c3ccccc3c3ccccc32)c1 ; c1ccc(-n2c3ccc(-n4c5ccccc5c5ccccc54)cc3c3cc(-n4c5ccccc5c5ccccc54)ccc32)cc1]

25. The method of claim 14, wherein the active layer is selected to have a bandgap no more than 2.1 eV.
